(19) United States
(12) Patent Application Publication
(10) Pub. No.: US 2004/0211998 A1
(43) Pub. Date: Oct. 28, 2004

(54) Lanthanide series layered superlattice materials for integrated circuit applications

(75) Inventors: Carlos A. Paz de Araujo, Colorado Springs, CO (US); Larry D. McMillan, Colorado Springs, CO (US); Narayan Solayappan, Colorado Springs, CO (US)

Correspondence Address: PATTON BOGGS, 1660 LINCOLN ST, SUITE 2050, DENVER, CO, 80264, US

(73) Assignee: Symetrix Corporation, Colorado Springs, CO

(21) Appl. No.: 10/851,703

(22) Filed: May 20, 2004

Related U.S. Application Data
(62) Division of application No. 09/998,364, filed on Nov. 29, 2001.

(51) Int. Cl. H01L 21/00; H01L 31/062

(52) U.S. Cl. 257/295; 438/3; 257/296; 438/238; 257/310

(57) ABSTRACT

An integrated circuit includes a layered superlattice material including one or more of the elements cerium, praseodymium, neodymium, promethium, samarium, europium, gadolinium, terbium, dysprosium, holmium, erbium, thulium, ytterbium, and lutetium. These elements may either be A-site elements or superlattice generator elements in the layered superlattice material. In one embodiment, one or more of these elements substitute for bismuth in a bismuth layered material. They also are preferably used in combination with one or more of the following elements: strontium, calcium, barium, bismuth, cadmium, lead, titanium, tantalum, hafnium, tungsten, niobium, zirconium, bismuth, scandium, yttrium, lanthanum, antimony, chromium, thallium, oxygen, chlorine, and fluorine. Some of these materials are ferroelectrics that crystallize at relatively low temperatures and are applied in ferroelectric non-volatile memories. Others are high dielectric constant materials that do not degrade or break down over long periods of use and are applied as the gate insulator in transistors or the charge storage device in volatile memories.

### BACKGROUND OF THE INVENTION

1. Field of the Invention

This invention relates to ferroelectric and high dielectric constant materials for use in integrated circuits (ICs), and more particularly to layered superlattice materials, such as layered perovskites.

2. Statement of the Problem

It has been postulated for at least 50 years that it may be possible to design a memory in which the memory element is a ferroelectric field effect transistor (FET). See Orlando Auciello, James F. Scott, and Ramamoorthy Ramesh, “The Physics of Ferroelectric Memories”, Physics Today, Vol. 51, No. 7, July 1998, pp. 22-27. Producing a working ferroelectric memory proved elusive until about ten years ago when the low fatigue properties of layered superlattice materials was discovered. See U.S. Pat. No. 5,519,234 issued May 21, 1996 to Paz de Araujo et al. Two general subclasses of layered superlattice materials are known. One well-known subclass is that in which one of the layers is perovskite like, and these are often referred to as “layered perovskites”. Another well-known subclass is one including all layered superlattice materials which contain bismuth, and these are often referred to as “bismuth layered materials” or “Bi-layered materials”. The layered superlattice materials have also proved to be useful as high dielectric constant materials in integrated circuits. See the U.S. Pat. No. 5,519,234 patent referenced above and U.S. patent application Ser. No. 09/686,552 filed 11 Oct. 2001 by Paz de Araujo et al.

While the layered superlattice materials disclosed in the above patent and others following it have lead to viable commercial ferroelectric memories and have proved useful as high dielectric constant materials in, for example, FETs and DRAMS, these materials generally need to be used with barrier layers and other structures that prevent migration of the materials in them to semiconductors and other materials in conventional integrated circuit devices, such as MOSFETS, that generally are used in combination with the layered materials. Moreover, the layered superlattice materials described in the prior art references generally can be formed only at relatively high temperatures ranging from 600° C. to 850° C., with the materials that can be made in the lower part of the range generally being inferior in key electrical properties, such as dielectric constant and polarizability. In addition, while the electronic properties of the prior art layered superlattice materials are sufficient to produce superior commercial devices, the properties are such that the fabrication processes must be carefully controlled to obtain the superior products. For example, while in the laboratory the prior art layered superlattice materials produce polarizabilities, 2Pr of up to 30 microcoulombs/cm² (μC/cm²), the constraints of commercial processing result in polarizabilities of about 12 μC/cm² to 18 μC/cm². Since polarizabilities of at least 7 μC/cm² are required for viable memories, and it is preferable to have a polarizability of about 12 μC/cm², there is not much room for error in the processing. Therefore, there remains a need for layered superlattice materials that are more compatible with conventional integrated circuit materials and structures, can be formed at lower temperatures, and have better electronic properties.

### SUMMARY OF THE INVENTION

The invention solves the above problem by providing layered superlattice materials containing the following elements: cerium (Ce), praseodymium (Pr), neodymium (Nd), promethium (PM), samarium (Sm), europium (Eu), gadolinium (Gd), terbium (Tb), dysprosium (Dy), holmium (Ho), erbium (Er), thulium (TM), ytterbium (Yb), and lutetium (Lu). These elements may either be A-site elements or superlattice generator elements in the layered superlattice material, though preferably they occupy A-site lattice points or partially substitute for bismuth in a bismuth layered material. In the latter case, lanthanum may also be used. They also are preferably used in combination with one or more of the following elements: strontium, calcium, barium, bismuth, cadmium, lead, titanium, tantalum, hafnium, tungsten, niobium, zirconium, bismuth, scandium, yttrium, lanthanum, antimony, chromium, thallium, oxygen, chlorine, and fluorine.

The new materials according to the invention may be ferroelectric or paraelectric, that is, normal dielectrics. They are preferably used in memories, capacitors, and transistors, including FETS, ferroelectric FETs, MOSFETs, but also may be used in other integrated circuit devices such as heterojunction bipolar transistors, BiCMOS devices, infrared sensitive cells, and other IC devices.

The invention provides an integrated circuit comprising: a substrate; and a thin film of a layered superlattice material formed on the substrate, the thin film comprising an element selected from the group consisting of cerium, praseodymium, neodymium, promethium, samarium, europium, gadolinium, terbium, dysprosium, holmium, erbium, thulium, ytterbium, and lutetium. Preferably, the thin film of a layered superlattice material also includes bismuth. Preferably, the thin film of a layered superlattice material also includes titanium. Preferably, the element comprises cerium, neodymium, dysprosium, or gadolinium. Preferably, the thin film is ferroelectric. Preferably, the thin film forms part of a memory.

In another aspect, the invention provides an integrated circuit comprising: a substrate; and a thin film of a layered superlattice material formed on the substrate, the layered superlattice material including an A-site element, a B-site element, a superlattice generator element, and an anion, the A-site element comprising an element selected from the group consisting of lanthanum, cerium, praseodymium, neodymium, promethium, samarium, europium, gadolinium, terbium, dysprosium, holmium, erbium, thulium, ytterbium, and lutetium.

In a further aspect, the invention provides an integrated circuit comprising: a substrate; and a thin film of a layered superlattice material formed on the substrate, the thin film having the formula A_{m-1pk (B}_{1-X}Lan_{X})₂MₘO₃ₘ₊₃, where A is an A-site element, M is a B-site element, O is oxygen, and m is an integer or a fraction, Lan represents one or more of the materials selected from the group consisting of lanthanum, cerium, praseodymium, neodymium, promethium, samarium, europium, gadolinium, terbium, dysprosium, holmium, erbium, thulium, ytterbium, and lutetium, and 0<x<1. Preferably, the layered superlattice material has the formula (B_{1-X}Lan_{X})₄Ti₃O₁₂. Preferably, 0.1≦x≦0.9. Most preferably, 0.1≦x≦0.5. Preferably, the formula comprises A(Bi_{1-X}Lan_{X})₂Ta_{1-y}Nb_{y}O₉ where A=Sr, Ca, Ba, or Pb and 1≦y≦0. Alternatively, the formula comprises (Bi_{1-X}Lan_{X})₂Bi₄Ti₃O₁₅. In a further embodiment, the formula comprises A(Bi_{1-X}Lan_{X})₄Ti₄O₁₅ where A=Sr, Ca, Ba, or Pb. In a further embodiment the formula comprises preferably A₂(Bi_{1-X}Lan_{X})₄Ti₅O₁₈, where A=Sr, Ca, Ba, or Pb. In yet another embodiment, the formula comprises (A_{Z-1}Lan_{[2/3]Z})ₘ₋₁Bi₂MₘO₃ₘ₊₃, where A is an A-site element other than a lanthanide, M is a B-site element, Lan is one or more of lanthanum, cerium, praseodymium, neodymium, promethium, samarium, europium, gadolinium, terbium, dysprosium, holmium, erbium, thulium, ytterbium, and lutetium, 0<z≦1 and m is an integer or a fraction; in this embodiment, preferably 0.1≦z≦0.9, and most preferably, 0.1≦z≦0.5. In this embodiment, the formula preferably comprises Lan_{2/3}Bi₂Ta_{y}Nb_{1-y}O₉, where 0≦y≦1. In still another embodiment, the formula comprises (A_{1-Z}Lan_{[2/3]Z})ₘ₋₁(Bi_{1-X}Lan_{X})₂MₘO₃ₘ₊₃, where 0<z<1; in this embodiment, the formula preferably comprises (Bi_{1-Z}Lan_{Z})_{2/3}(Bi_{1-X}Lanₓ)₂B₂O₉ where B is a B-site element. In all the forgoing embodiments, preferably, the thin film of a layered superlattice material includes titanium. Preferably, in the above embodiments, Lan preferably represents lanthanum, neodymium, dysprosium, cerium, or gadolinium. Also, the thin film is preferably ferroelectric, and the thin film forms part of a memory.

In another aspect, the invention provides an integrated circuit comprising: a substrate; and a thin film of a bismuth layered material formed on the substrate, wherein a lanthanide element is partially substituted for the bismuth in the bismuth layered material.

In yet a further aspect, the invention provides a method of fabricating a memory device, the method comprising: providing a substrate; forming a memory cell on the substrate, the process of forming the memory cell on the substrate including spontaneously forming a layered superlattice material structure in a thin film, the layered superlattice material including an element selected from the group consisting of cerium, praseodymium, neodymium, promethium, samarium, europium, gadolinium, terbium, dysprosium, holmium, erbium, thulium, ytterbium, and lutetium; and completing the memory on the substrate. Preferably, the layered superlattice material also includes bismuth. Preferably, the layered superlattice material also includes titanium. Preferably, the element comprises lanthanum, neodymium, cerium, dysprosium, or gadolinium. Preferably, the layered superlattice material is ferroelectric.

In still a further aspect, the invention also provides a method of fabricating an integrated circuit, the method comprising: providing a substrate; forming on the substrate a thin film of a layered superlattice material, the layered superlattice material including an element selected from the group consisting of cerium, praseodymium, neodymium, promethium, samarium, europium, gadolinium, terbium, dysprosium, holmium, erbium, thulium, ytterbium, and lutetium; and completing the integrated circuit on the substrate.

In yet a further aspect, the invention provides a method of fabricating a ferroelectric memory, the method comprising: forming a first electrode on a substrate;. forming a thin film of a ferroelectric layered superlattice material on the first electrode, the layered superlattice material including an element selected from the group consisting of cerium, praseodymium, neodymium, promethium, samarium, europium, gadolinium, terbium, dysprosium, holmium, erbium, thulium, ytterbium, and lutetium; and forming a second electrode on the ferroelectric layered superlattice material.

In still another aspect, the invention provides a method of fabricating a ferroelectric layered superlattice material comprising the steps of: providing a substrate; providing a liquid precursor including a plurality of metals suitable for forming a layered superlattice material, the metals including an element selected from the group consisting of cerium, praseodymium, neodymium, promethium, samarium, europium, gadolinium, terbium, dysprosium, holmium, erbium, thulium, ytterbium, and lutetium; applying the precursor liquid to the substrate; and treating the precursor on the substrate to form a layered superlattice material containing the metal on the first substrate. Preferably, the precursor liquid comprises a metal compound selected from the group consisting of metal alkoxides and metal carboxylates. Preferably, the precursor liquid comprises a metal compound including an alkoxide of one of the metals in the group. Preferably, the liquid precursor comprises octane. Preferably, the applying and treating comprises metalorganic chemical vapor deposition (MOCVD). Preferably, the MOCVD is performed at a temperature of from 500° C. to 850° C., and most preferably at a temperature of from 500° C. to 700° C. Preferably, the treating comprises a process selected from the group consisting of: exposing to vacuum, exposing to ultraviolet radiation, electrical poling, drying, heating, baking, rapid thermal processing (RTP), and annealing. Preferably, the treating includes drying at a temperature of 300° C. or less. Preferably, the treating comprises furnace annealing at a temperature of from 500° C. to 750° C. Preferably, the treating comprises RTP at a temperature of from 500° C. to 750° C. Alternatively, the applying comprises a spin-on process or a misted deposition process. Preferably, the layered superlattice material also includes bismuth. Preferably, the precursor contains bismuth in excess of the stoichiometric amount required to form the layered superlattice material. Preferably, the layered superlattice material also includes titanium. Preferably, the element comprises lanthanum, neodymium, cerium, dysprosium, or gadolinium.

The invention not only provides a ferroelectric memory that is more compatible with conventional integrated circuit elements, but also provides one that is more manufacturable and more-environmentally compatible. Other features, objects and advantages of the invention will become apparent from the following description when read in conjunction with the accompanying drawings.

### BRIEF DESCRIPTION OF THE DRAWINGS

FIG. 1 shows a cross-sectional view of a preferred embodiment of a ferroelectric FET memory cell in accordance with the invention;

FIG. 2 illustrates one alternative embodiment of the gate structure of a FET in accordance with the invention;

FIG. 3 is a cross-sectional view a DRAM or FERAM memory cell having a field effect transistor and capacitor in accordance with the invention;

FIG. 4 is a cross-sectional view of an alternative embodiment of an MFM-MIS FET in accordance with the invention;

FIG. 5 shows a portion of an alternative embodiment of a ferroelectric memory in which groups of memory cells are serially linked;

FIG. 6 is a block circuit diagram of an integrated circuit memory in accordance with the invention utilizing memory cells such as those shown in FIGS. 1-4 or groups of cells such as shown in FIG. 5; and

FIG. 7 is a flow sheet of the fabrication steps of a method 310 in accordance with the invention to make a ferroelectric memory.

### DETAILED DESCRIPTION OF THE PREFERRED EMBODIMENT

1. Overview

As mentioned above, and as discussed in detail below, materials referred to herein as “layered superlattice materials” are particularly well suited for use in integrated circuit devices, particularly integrated circuit memories. In Section 2, below, we shall provide a generalized discussion of the layered superlattice materials and the particular novel chemical elements used in the materials of the invention. Section 2 also includes a discussion of exemplary devices in which the materials of the invention are used. In Section 3, exemplary formulations of the layered superlattice materials including the novel elements will be disclosed. These exemplary formulations provide electronic properties that are superior to the electronic properties of prior art layered superlattice materials, and, in particular, far superior to any prior art ferroelectric material. In Section 4, examples of the fabrication of integrated circuit devices containing the inventive materials will be provided.

2. Exemplary Structures And Materials of The Invention

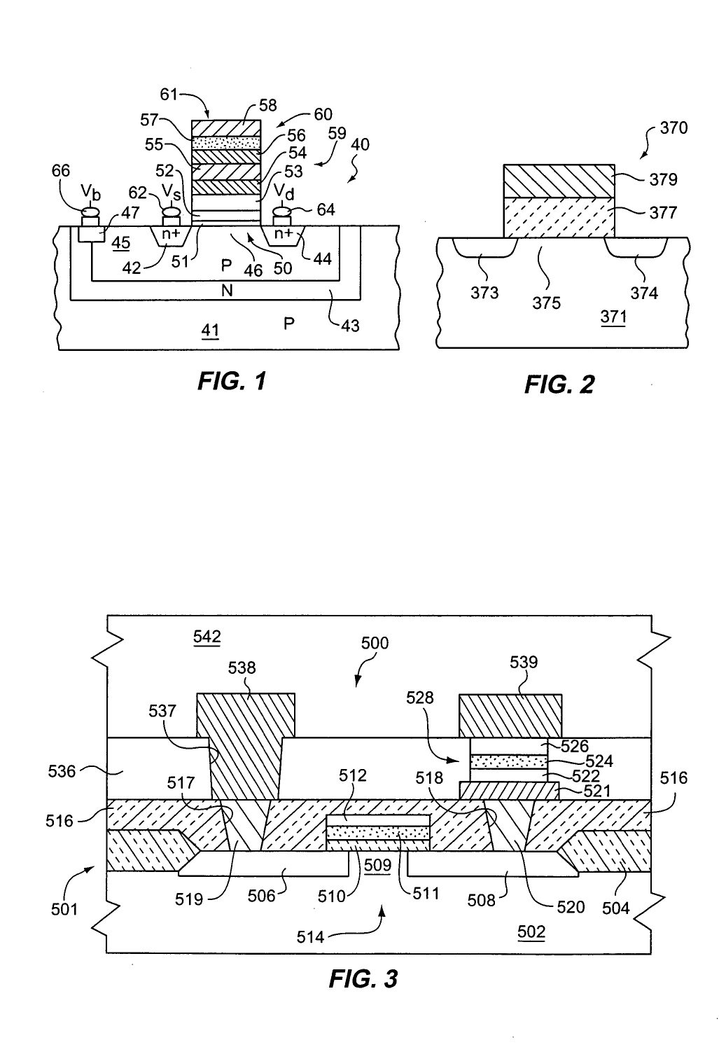

Directing attention to FIG. 1, a cross-sectional view of a ferroelectric FET 40 in accordance with the invention is shown. FET 40 includes a relatively complex FET structure, designed to illustrate in one place all the many layers that can be associated with a typical ferroelectric FET (FeFET). However, it should be understood that all of the layers except gate electrode 58 and ferroelectric layer 57 are optional. The FET 40 includes a substrate 41 which is preferably p-type silicon, but may be any other appropriate semiconductor, such as gallium arsenide, silicon germanium, and others. A deep well 43, preferably an n-type well, is formed in substrate 41, and a less deep well 45, preferably a p-type well, is formed within well 43. Doped active areas 42 and 44, preferably n-type, are formed in well 45. We shall generally refer to these active areas 42 and 44 herein as source/drains since they can either be a source or a drain depending on the relative voltages applied to the areas. A channel region 46, preferably also n-type, but not as highly doped as source/drains 42 and 44, is formed between source/drains 42 and 44. A gate structure 61 is formed on substrate 41 above channel region 46. In the preferred embodiment, gate structure 61 is a mutilayer structure, though usually it will not include all the layers 51 through 58 shown in FIG. 1. That is, gate structure 61 shown in FIG. 1 is intended to illustrate the layers that could be included in the structure. The fundamental layers involved are an insulating layer 50, a floating gate layer 59, a ferroelectric layered superlattice material layer 57, and a gate electrode layer 58. Insulating layer 50, often referred to as the “gate oxide”, is shown as a multilayer structure comprising layers 51, 52, and 53, each of which is a different insulator. Preferably, layer 51 is an insulator closely related to the material of substrate 41. Preferably, layer 52 is a buffer or interface layer that can perform one or both of two functions: assisting in the adhesion of the layers above it to the layer below it; and preventing the migration of elements in the layers above it to the layers below it. Insulating layer 53 is considered to be the primary insulating layer of the gate, and is preferably a material having dielectric properties suitable for effective operation of the FET. It should be understood that a single material may perform the functions of layers 52 and 53, or even of all three layers 51, 52, and 53. A floating conducting gate 59 is formed on insulating layer 50. Again, the floating gate is shown as three layers, 54, 55, and 56. In one embodiment, layer 54 is a polysilicon layer, layer 55 is an adhesion layer, and layer 56 is a layer of a metal, such as platinum. In another embodiment, layer 54 is an adhesion layer that assists in adhesion of floating gate 59 to the layer below it. In this embodiment, layer 55 is considered to be the primary floating gate layer, and layer 56 is a conducting barrier layer, the purpose of which is to prevent the migration of elements in the layers above it to the layers below it. A ferroelectric layered superlattice material layer 57 is formed on floating gate 59. A gate electrode 58 is formed on ferroelectric layered superlattice material layer 57. It should be understood that ferroelectric layer 57 and gate electrode 58 can also be multilayer structures, though generally they are not. Wiring layers form electrical contacts 62, 64, and 66 to source/drain 42, source/drain 44, and substrate 41, respectively. Contact 66 is preferably located over a shallow p-well 47 at the junction between deep well 43 and well 45. Gate 58 is preferably integral with its own wiring layer, so a contact is not shown. As will be discussed in more detail below, in ferroelectric FET 40, the charge storage element is the ferroelectric layered superlattice material layer 57.

Preferably, when semiconductor 41 is silicon, insulating layer 51 is silicon dioxide. Preferably, insulating layer 52 is a buffer or interface layer, the purpose of which is to prevent elements in the layers above it from migrating into the semiconductor layer below it. It also may assist in adhering the layers above it to the layers below it. Buffer layer 52 preferably comprises Ta₂O₅, but may also be CeO₂ or any other suitable material that either prevents elements from migrating and/or assists in adhering the: layers above it to the silicon layers below it. Layer 53 is a gate insulator which preferably comprises one or more materials selected from: Ta₂O₅, SiO₂, CeO₂, ZrO₂, Y₂O₃, YMnO₂, and SrTa₂O₆. Its thickness is preferably 4 nanometers (nm) to 50 nm. In one preferred embodiment, gate insulator 50 comprises a layer 51 of silicon dioxide and a layer 53 of Ta₂O₅. In this case, the layer of Ta₂O₅ acts as the primary gate insulator and a buffer layer as well. In other embodiments, gate insulator 53 is a high dielectric constant insulator comprising one or more of the layered superlattice materials according to the invention.

Ferroelectric layered superlattice materials are described in U.S. Pat. No. 5,519,234 issued May 21, 1996 to Paz de Araujo et al.; U.S. Pat. No. 5,434,102 issued Jul. 18, 1995 to Watanabe et al.; U.S. Pat. No. 5,784,310 issued Jul., 22, 1998 to Cuchiaro et al.; U.S. Pat. No. 5,840,110 issued Nov. 24, 1998 to Azuma et al., and U.S. patent application Ser. No. 08/405,885 filed Mar. 17, 1995 in the name of Azuma et al., all of which are incorporated herein by reference as though fully disclosed herein.

The layered superlattice materials have been catalogued by G. A. Smolenskii and others. See Chapter 15 of the book Ferroelectrics and Related Materials, ISSN 0275-9608, (V. 3 of the series Ferroelectrics and Related Phenomena, 1984) edited by G. A. Smolenskii, especially Sections 15.3-15.7; G. A. Smolenskii, A. I. Agranovskaya, “Dielectric Polarization of a Number of Complex Compounds”, Fizika Tverdogo Tela, V. 1, No. 10, pp. 1562-1572 (October 1959); G. A. Smolenskii, A. I. Agranovskaya, V. A. Isupov, “New Ferroelectrics of Complex Composition”, Soviet Physics—Technical Physics, pp, 907-908 (1959); G. A. Smolenskii, V. A. Isupov, A. I. Agranovskaya, “Ferroelectrics of the Oxygen-Octahedral Type With Layered Structure”, Soviet Physics—Solid State, V. 3, No. 3, pp. 651-655 (September 1961); E. C. Subbarao, “Ferroelectricity in Mixed Bismuth Oxides With Layer-Type Structure”, J. Chem. Physics, V. 34, p. 695 (1961); E. C. Subbarao, “A Family of Ferroelectric Bismuth Compounds”, J. Phys. Chem. Solids, V. 23, pp. 665-676 (1962); and Chapter 8, pp. 241-292 and pp. 624-625 of Appendix F of Principles and Applications of Ferroelectrics and Related Materials, by M. E. Lines and A. M. Glass, Clarendon Press, Oxford, 1977, pp. 620-632. These materials may be represented by the formulae outlined by Smolenskii:

(I) compounds having the formula Aₘ₋₁Bi₂MₘO₃ₘ₊₃, where A=Bi³⁺, Ba²⁺, Sr²⁺, Ca²⁺, Pb²⁺, K⁺, Na⁺ and other ions of comparable size, and M=Ti⁴⁺, Nb⁵⁺, Ta⁵⁺, Mo⁶⁺, W⁶⁺, Fe³⁺ and other ions that occupy oxygen octahedral; this group includes bismuth titanate, Bi₄Ti₃O₁₂; these shall be referred to as the Smolenskii Type I compounds herein;

(II) compounds having the formula Aₘ₊₁MₘO₃ₘ₊₁, including compounds such as strontium titanates Sr₂TiO₄, Sr₃Ti₂O₇ and Sr₄Ti₃O₁₀; these shall be referred to as the Smolenskii Type II compounds herein; and

(III) compounds having the formula AₘMₘO₃ₘ₊₂, including compounds such as Sr₂Nb₂O₇, La₂Ti₂O₇, Sr₅TiNb₄O₁₇, and Sr₆Ti₂Nb₄O₂₀. It is noted that in the case of Sr₂Nb₂O₇ and La₂Ti₂O₇, the formula needs to be doubled to make them agree with the general formula; these shall be referred to as the Smolenskii Type III compounds herein.

The materials of the invention include all of the above materials plus combinations and solid solutions of these materials which include A-site elements or superlattice generator elements that include the specified lanthanides. The layered superlattice materials may be summarized generally under the formula:

A1_{w1}^{+a1}A2_{w2}^{+a2} . . . Aj_{wj}^{+aj}S1ₓ₁^{+s1}S2ₓ₂^{+s2} . . . Skₓₖ^{+sk}B1_{y1}^{+b1}B2_{y2}^{+b2} . . . Bl_{yl}^{+bl}Q_{z}⁻² (1)

where A1, A2 . . . Aj represent A-site elements in the structure, which may be elements such as strontium, calcium, barium, bismuth, lead, cerium, praseodymium, neodymium, promethium, samarium, europium, gadolinium, terbium, dysprosium, holmium, erbium, thulium, ytterbium, and lutetium and others; S1, S2 . . . Sk represent superlattice generator elements, which usually is bismuth, but can also be materials such as yttrium, scandium, lanthanum, antimony, chromium, thallium, cerium, praseodymium, neodymium, promethium, samarium, europium, gadolinium, terbium, dysprosium, holmium, erbium, thulium, ytterbium, and lutetium and other elements with a valence of +3; B1, B2 . . . Bl represent B-site elements in the structure, which may be elements such as titanium, tantalum, hafnium, tungsten, niobium, zirconium, and other elements; and Q represents an anion, which generally is oxygen but may also be other elements, such as fluorine, chlorine and hybrids of these elements, such as the oxyfluorides, the oxychlorides, etc. The superscripts in Formula (1) indicate the valences of the respective elements; for example, if Q is oxygen, then q=2. The subscripts indicate the number of moles of the material in a mole of the compound, or in terms of the unit cell, the number of atoms of the element, on the average, in the unit cell. The subscripts can be integer or fractional. That is, Formula (1) includes the cases where the unit cell may vary uniformly throughout the material; for example, in Dy_{2/3}Bi₂(Ta_{0.75}Nb_{0.25})₂O₉, 75% of the B-sites are occupied by tantalum atoms, and 25% of the B-sites are occupied by niobium atoms. If there is only one A-site element in the compound, then it is represented by the “A1” element and w2 . . . wj all equal zero. If there is only one B-site element in the compound, then it is represented by the “B1” element, and y2 . . . yl all equal zero, and similarly for the superlattice generator elements. The usual case is that there is one A-site element, one superlattice generator element, and one or two B-site elements, although Formula (1) is written in the more general form since the invention is intended to include cases where the A-sites, B-sites and the superlattice generator can have multiple elements. The value of z is found from the equation:

(a1w1+a2w2 . . . +ajwj)+(s1x1+s2x2 . . . +skxk)+(b1y1+b2y2 . . . +blyl) =qz. (2)

Formula (1) includes all three of the Smolenskii type compounds discussed in U.S. Pat. No. 5,519,234 issued May 21, 1996, referenced above. The layered supedattice materials do not include every material that can be fit into Formula (1), but only those that form crystalline structures with distinct alternating layers. The layered superlattice materials according to the invention are such materials that include the following elements: cerium, praseodymium, neodymium, promethium, samarium, europium, gadolinium, terbium, dysprosium, holmium, erbium, thulium, ytterbium, and lutetium.

Formula (1) includes all three of the Smolenskii type compounds: for the Type I material, w1=m−1, x1=2, y1=m, z=3m+3 and the other subscripts equal zero; for the Type II material, w1=m+1, y1=m, z=3m+1, and the other subscripts equal zero; for the Type III material, w1=m, y1=m, z=3m+2, and the other subscripts equal zero. It is noted that the Smolenskii Type I formula does not work for M=Ti and m=2, while the Formula (1) does work. This is because the Smolenskii formula does not consider valences. The layered superlattice materials do not include every material that can be fit into the Formula (1), but only those which form crystalline structures with distinct alternating layers during crystallization. Crystallization is typically assisted by thermally treating or annealing the mixture of precursor ingredients. The enhanced temperature facilitates ordering of the superlattice-forming moieties into thermodynamically favored structures, such as perovskite-like octahedra. The term “superlattice generator elements” as applied to S1, S2 . . . Sk, refers to the fact that these metals are particularly stable in the form of a concentrated metal oxide layer interposed between two perovskite-like layers, as opposed to a uniform random distribution of superlattice generator metals throughout the mixed layered superlattice material. In particular, bismuth has an ionic radius that permits it to function as either an A-site material or a superlattice generator, but bismuth, if present in amounts less than a threshold stoichiometric proportion, will spontaneously concentrate as a non-perovskite-like bismuth oxide layer. It should also be understood that the term “layered superlattice material” herein also includes doped layered superlattice materials. That is, any of the material included in Formula (1) may be doped with a variety of materials, such as silicon, germanium, uranium, zirconium, tin or hafnium. In summary, the materials of the invention include all the materials as described by the Smolenskii formulae and Formula (1) that include the elements cerium, praseodymium, neodymium, promethium, samarium, europium, gadolinium, terbium, dysprosium, holmium, erbium, thulium, ytterbium, and lutetium, plus solid solutions of all the foregoirig materials. Generally, the preferred layered superlattice materials include the polycrystalline thin films of these layered superlattice materials. The preferred formulations for the materials of the invention will be given in detail below.

The word “superlattice” herein may mean something slightly different than it means in some physics contexts, such as superconductivity. Sometimes the word “superlattice” carries with it connotations of single crystal structures only. However, the materials in accordance with the invention are preferably not single crystals. In fact, none of the materials produced to date are single crystals, though it is believed that single crystals of these materials can be made. The materials of the invention are preferably polycrystalline. In the polycrystalline state, the structure of the materials includes grain boundaries, point defects, dislocation loops and other microstructure defects. However, for the perovskite-like materials cataloged by Smolenskii and others, within each grain, the structure is predominately repeatable units containing one or more perovskite-like layers and one or more intermediate non-perovskite-like layers spontaneously linked in an interdependent manner. It will be recognized by those skilled in the art that the term “layered superlattice materials” is intended to include all materials that spontaneously form themselves into crystal structures that include a first layer and a second layer, with the first and second layers having distinctly different crystal structures. The ones of these material that form perovskite-like crystal structures are sometimes referred to as layered perovskites, and those that include bismuth are sometimes referred to as Bi-layered materials. Heterostructures, such as compositional superlattices, are not included.

The term “stoichiometric” herein may be applied to both a solid film of a material, such as a layered superlattice material, or to the precursor for forming a material. When it is applied to a solid thin film, it refers to a formula which shows the actual relative amounts of each element in a final solid thin film. When applied to a precursor, it indicates the molar proportion of metals in the precursor. A “balanced” stoichiometric formula is one in which there is just enough of each element to form a complete crystal structure of the material with all sites of the crystal lattice occupied, though in actual practice there always will be some defects in the crystal at room temperature. For example, both Nd_{2/3}Bi₂(TaNb)O₉ and Nd_{2/3}Bi₂(Ta_{1.5}Nb_{0.5})O₉ are balanced stoichiometric formulae. In contrast, a precursor for dysprosium bismuth tantalum niobate in which the molar proportions of dysprosium, bismuth, tantalum, and niobium are 0.6, 2.18, 1.5, and 0.5, respectively, is represented herein by the unbalanced “stoichiometric” formula Nd_{0.6}Bi_{2.18}(Ta_{1.5}Nb_{0.5})O₉, since it contains excess bismuth and deficient dysprosium relative to the B-site elements tantalum and niobium. It is common in the art to write an unbalanced stoichiometric formula of a metal oxide in which the subscript of the oxygen symbol is not corrected to balance completely the subscript values of the metals.

The word “precursor” used herein can mean a solution containing one metal organic solute that is mixed with other precursors to form intermediate precursors or final precursors, or it may refer to a final liquid precursor solution, that is, the solution to be applied to a particular surface during fabrication. The precursor as applied to the substrate is usually referred to as the “final precursor”, “precursor mixture”, or simply “precursor”. In any case, the meaning is clear from the context.

The term “thin film” is used herein as it is used in the integrated circuit art. Generally, it means a film of less than a micron in thickness. The thin films disclosed herein are in most instances 0.5 microns in thickness or less. These thin films of the integrated circuit art should not be confused with the so-called “thin films” in layered capacitors of the macroscopic capacitor art which are formed by a wholly different process which is incompatible with the integrated circuit art.

Floating gate 59 and gate 58 are preferably made of platinum, though they may be any other suitable conductor. As shown in FIG. 1, floating gate 59, which is sometimes referred to in the art as the bottom electrode, may be a multilayer structure which may include an adhesive layer 54 or 55, depending on the embodiment. The adhesion layer is typically titanium and preferably approximately 20 nm thick. The layer above the adhesion layer is preferably an approximately 100 nm to 200 nm thick layer of platinum. Floating gate 59 may also include a barrier layer 56, which preferably is Ta₂O₅, but may be IrO₂ or other material, preferably about 4 nm to 40 nm thick. The only essential parts of FET 40 are semiconductor 41, ferroelectric layered superlattice material layer 57, and gate 58. The other layers are optional. One or more may be omitted in any specific embodiment. Further, the order of the layers 51-58 may be varied, and additional layers may be added.

It should be understood that the FIGS. 1-4 depicting integrated circuit devices are not meant to be actual plan or cross-sectional views of any particular portion of an actual integrated circuit device. In the actual devices, the layers will not be as regular and the thickness will generally have different proportions. The figures instead show idealized representations that are employed to depict more clearly and fully the structure and process of the invention than would otherwise be possible. For example, if the various thickness of the layers were correct relative to one another, the drawing of the FET would either have layers that are too small to see clearly or would not fit on the paper.

Terms of orientation herein, such as “above”, “over”, “top”, “upper”, “below”, “bottom” and “lower”, mean relative to semiconductor substrate 41. That is, if a second element is “above” a first element, it means it is farther from substrate 41, and if it is “below” another element then it is closer to substrate 41 than the other element. The long dimension of substrate 41 defines a substrate plane that is defined by the horizontal direction and the direction into and out of the paper in FIG. 1. Planes parallel to this plane are called a “horizontal” plane herein, and directions perpendicular to this plane are considered to be “vertical”. A memory cell typically comprises relatively flat thin film layers. The terms “lateral” or “laterally” refer to the direction of the flat plane of the thin film layers. In FIG. 1, the lateral direction would be the horizontal direction. The terms “underlie” and “overlie” are also defined in terms of substrate 41. That is, if a first element “underlies” a second “overlying” element, it means that a line perpendicular to the substrate plane that passes through the first element also passes through the second element.

This specification refers to a buffer and/or barrier layer located between a semiconductor and thin film of ferroelectric or dielectric material. The term “between” does not mean that the buffer and/or barrier layer is in direct contact with the thin film of ferroelectric material or the semiconductor. The buffer and/or barrier layer may contact the ferroelectric or semiconductor, but typically, it does not. The term “on” is also sometimes similarly used in the specification when referring to the deposition or formation of an integrated circuit layer onto an underlying substrate or layer. In contrast to “between” or “on” , the term “directly on” signifies direct contact, as is clear in the various contexts in which it is used.

In this disclosure, the terms “row” and “column” are relative terms that are used to facilitate the disclosure. That is, conventionally, a row is a horizontal line or alignment and a column is a vertical line or alignment. However, the invention contemplates that in any array, rows can become columns and columns can become rows simply by viewing the array from a perspective that is rotated by 90 degrees, 270 degrees, etc. Thus, because a memory architecture is rotated by 90 degrees, 270 degrees, etc., from the invention described in the summary of the invention, the specification, or claims herein, but otherwise is the same, does not take it outside of the architectures contemplated by the invention.

The term “high dielectric constant” means a dielectric constant of ten or greater. Conventional dielectrics in integrated circuit capacitors and transistors have a dielectric constant of about 4 or 5. Thus, a high dielectric constant material has a dielectric constant of at least twice the dielectric constant of a conventional dielectric material used in an integrated circuit.

Returning to FIG. 1, during operation, a voltage, Vₛ, is applied to source 42, a voltage, V_{b}, is applied to substrate 41, a voltage, V_{d}, is applied to drain 44, and a gate voltage, V_{g}, is applied to gate 58. These voltages may either be a high or logic “1” voltage, a low, or logic “0” voltage, an open or high resistance state, generally designated as “Z” herein, or a small positive or negative voltage between the logic “0” and logic “1” states. In the preferred embodiment of the read process, the drain voltage Vd takes on a small positive value, which generally is significantly less than the high voltage.

For example, if a positive write bias voltage, V_{g}, is applied to gate 58, then the resulting electric field exerted on ferroelectric thin film 57 causes ferroelectric thin film 57 to be polarized, even after the voltage and field are no longer applied. The remnant polarization in ferroelectric thin film 57 exerts an electric field through interface insulating layer 50 into channel region 46, attracting electrons into channel region 46, and thereby causing an increase of free electrons available for conduction of electric current. As a result, when drain voltage, V_{d}, is applied to drain region 44 in a read operation, a current sensor senses high current across channel region 46, and reads a binary “1” state. When a negative V_{g} is applied to gate 58 in the write operation, then the resulting remnant polarization in ferroelectric thin film 57 repels current-carrying electrons from, or attracts positive holes into, channel region 46, and the resulting low current is sensed as the binary “0” state when V_{d} is applied to drain 42 in a read operation. The write bias voltage, V_{g}, and the read bias voltage, V_{d}, are typically in the range of 1 volt to 15 volts, and most preferably in the range of about 2 volts to 5 volts. Preferably, the low or logic “0” voltage is zero or the ground state. If the voltage across ferroelectric 57 is equal to or greater than the coercive voltage, essentially all the ferroelectric domains in the material 57 will become polarized; but even a small voltage, e.g. 1.0 volt, will cause some domains to switch.

From the above discussion, it is seen that the data stored in the ferroelectric FET 40 is stored as a polarization charge in the ferroelectric layered superlattice material layer 57. Thus, ferroelectric layer 57 is the charge storage element of the. FeFET.

As known in the art, if a ferroelectric FET is to provide a workable memory, a graph of gate voltage versus drain current must follow a hysteresis curve. Starting at a zero gate voltage, there is essentially no drain current, because the resistance in channel 46 is very high. As the gate voltage increases, there remains no drain current until a positive threshold voltage, +Vₜₕ, is reached. At this voltage, ferroelectric 57 switches into the ON state and attracts carriers into channel 46 causing a drain current. Then, as the gate voltage continues to increase, the drain current increases linearly until a saturation current, Iₛₐₜ, is approached. After saturation, as the gate voltage increases, there is no increase in current, and the curve continues flat. As the gate voltage is decreased, the drain current remains the same until a negative threshold voltage, −Vₜₕ, is approached. Then the drain current decreases linearly until it approaches the point where the ferroelectric switches into the OFF state, at which point the drain current goes to zero. The drain current remains at zero no matter how large a negative voltage is applied, and, as the voltage is increased, does not rise above zero until the positive threshold voltage is reached. The area of the hysteresis curve is called the “memory window”. To obtain a workable memory device, the width of the memory window, i.e. +Vₜₕ to −Vₜₕ, must be greater than the noise in gate electrode 58, and the height of the memory window, i.e. Iₛₐₜ, must be greater than the noise in the drain and associated sense circuit. For a non-volatile memory, the zero volts line should ideally be centered in the memory window, or at least well within the noise margins, since the device should retain the data without external power. A high ratio of Iₛₐₜ in the ON state and Iₛₐₜ in the OFF state is also desirable to permit ease of discrimination of the two states by the sensing circuit.

The memory window for an exemplary ferroelectric FET including a layered superlattice material in accordance with the invention in which the DC gate bias was swept from −10 volts to +10 volts and back has been measured at approximately 4.3 volts, and the center of the window was at approximately one volt. The difference between the ON current and the OFF current was ten decades; thus, the polarization was easily distinguishable.

The invention contemplates that the materials of the invention can be used with any FET structure. FIGS. 1-4 illustrate various FET gate and capacitor configurations and associated structures in which the materials in accordance with the invention may be used. For easier understanding, the details of the substrate architecture are not shown in these figures. However, it should be understood that in the preferred embodiment they would include deep—and/or p- wells as shown in FIG. 1. In alternative embodiments, they can be combined with other substrate architectures as well.

FIG. 2 shows an MFSFET 370 that can also serve as the FET to implement the invention. This FET is again formed on a semiconductor 371, and includes source/drains 373 and 374, channel 375, ferroelectric 377, and electrode 379. Contacts, wiring layers and other architecture can take on any of the forms shown or discussed above or below.

FIG. 3 shows a charge storage device, i.e., memory cell 500, in which the material in accordance with the invention is used as a gate insulator 511, as a capacitor dielectric 524, and can also be used in an ILD 536, in some embodiments. Memory cell 500 includes transistor 514 and capacitor 528 formed on a wafer 501 including semiconductor substrate 502. Semiconductor substrate 502 may comprise silicon, gallium arsenide, silicon germanium, or other semiconductor, and may also include other substrate materials such as ruby, glass or magnesium oxide. In the preferred embodiment, it is silicon. A field oxide region 504 is formed on a surface of semiconductor substrate 502. Semiconductor substrate 502 comprises a highly doped source region 506 and a highly doped drain region 508, which are formed about a doped channel region 509. Doped source region 506, drain region 508, and channel region 509 are preferably n-type doped regions, but also may be p-type. Buffer/diffusion barrier layer 510, comprising a thin film of electrically nonconductive material in accordance with the invention, is located on semiconductor substrate 502, above channel region 509. Buffer/diffusion barrier layer 510 has a thickness in the range of from 1 nm to 30 nm, preferably from 1 nm to 5 nm. A gate insulator 511 comprising a thin film of high dielectric constant insulator in accordance with the invention is located on buffer/diffusion barrier layer 510. Further, a gate electrode 512 is located on gate insulator 511. Gate insulator 511 has a thickness in the range of from 1 nm to 50 nm, preferably from 5 nm to 20 nm. These source region 506, drain region 508, channel region 509, buffer/diffusion barrier layer 510, gate insulator 511, and gate electrode. 512 together form a MOSFET 514.

A first interlayer dielectric (“ILD”) layer 516, preferably made of BPSG (boron-doped phospho-silicate glass) is located on semiconductor substrate 502 and field oxide region 504. ILD 516 is patterned to form vias 517, 518 to source region 506 and drain region 508, respectively. Vias 517, 518 are filled to form plugs 519, 520, respectively. Plugs 519, 520 are electrically conductive and typically comprise polycrystalline silicon, tungsten, or tantalum but may be any other suitable conductor. An electrically conductive buffer/diffusion barrier layer 521 in accordance with the invention is located on ILD 516 in electrical contact with plug 520. Conductive diffusion barrier layer 521 is typically made of IrO₂, but may be made of other materials and typically has a thickness of from 1 nm to 30 nm, preferably from 1 nm to 5 nm.

As depicted in FIG. 3, a bottom electrode layer 522 is located on diffusion barrier layer 521. It is preferable that the bottom electrode contains a non-oxidized precious metal such as platinum, palladium, silver, and gold. In addition to the precious metal, metals such as aluminum, aluminum alloy, aluminum silicon, aluminum nickel, nickel alloy, copper alloy, and aluminum copper may be used for electrodes of a dielectric or ferroelectric memory. In the preferred embodiment, bottom electrode 522 is made of platinum and has a thickness of 100 nm. Preferably, it also includes at least one adhesive layer (not shown), such as titanium, to enhance the adhesion of the electrodes to adjacent underlying or overlying layers of the circuits. Capacitor dielectric 524, comprising a thin film of high dielectric constant insulator in accordance with the invention, is located on bottom electrode layer 522. Capacitor dielectric 524 has a thickness in the range of from 5 nm to 500 nm, preferably from 30 nm to 100 nm. A top electrode layer 526, made of platinum and having a thickness of 100 nm, is formed on capacitor dielectric 524. Bottom electrode layer 522, thin film capacitor dielectric 524, and top electrode layer 526 together form memory capacitor 528. Diffusion barrier layer 521 inhibits the diffusion of metal atoms and oxygen from capacitor dielectric 524 and bottom electrode 522 into the semiconductor substrate. A second interlayer dielectric layer (ILD) 536, preferably made of NSG (nondoped silicate glass) is deposited to cover ILD 516, buffer/diffusion barrier layer 521, and dielectric memory capacitor 528. A PSG (phospho-silicate glass) film or a BPSG (boron phospho-silicate glass) film or other insulator could also be used in layer 536. ILD 516 and particularly ILD 536 may also be made of the layered superlattice material in accordance with the invention; however, because of the high dielectric constant, care should be taken with placement of metallization layers to avoid creating capacitive structures. If such care is taken, then the materials of the invention used as an ILD can have many advantages, such as acting to protect the critical layered superlattice elements 511 and 524 from degradation to hydrogen and other process gases. ILD 536 is patterned to form via 537 to plug 519. A metallized wiring film is deposited to cover ILD 536 and fill via 537 and then patterned to form source electrode wiring 538 and top electrode wiring 539. Wirings 538, 539 preferably comprise Al—Si—Cu standard interconnect metal with a thickness of about 200 nm to 300 nm, but may include other metals mentioned above.

The structure shown in FIG. 3 in which capacitor 528 is stacked on top of ILD 536 and thus separated from transistor 514 is conventionally called a “stacked capacitor” structure and the process of making a structure such as this is well-known in the art. If layer 524 is a high dielectric constant material, integrated circuit charge storage device 500 is a DRAM cell; if layer 524 is a ferroelectric, then device 500 is a FERAM cell. The non-ferroelectric high dielectric constant materials of the invention may be used as gate dielectric 511, capacitor dielectric material 524, or interlayer dielectric 516 or 536.

As known in the art, whether transistor 514 is “on” or “off” is determined by whether or not sufficient charge is stored in gate insulator 511 or at the interfaces of the insulator with its corresponding gate and channel; thus, insulator 511 can also be referred to as the charge storage element of the FET.

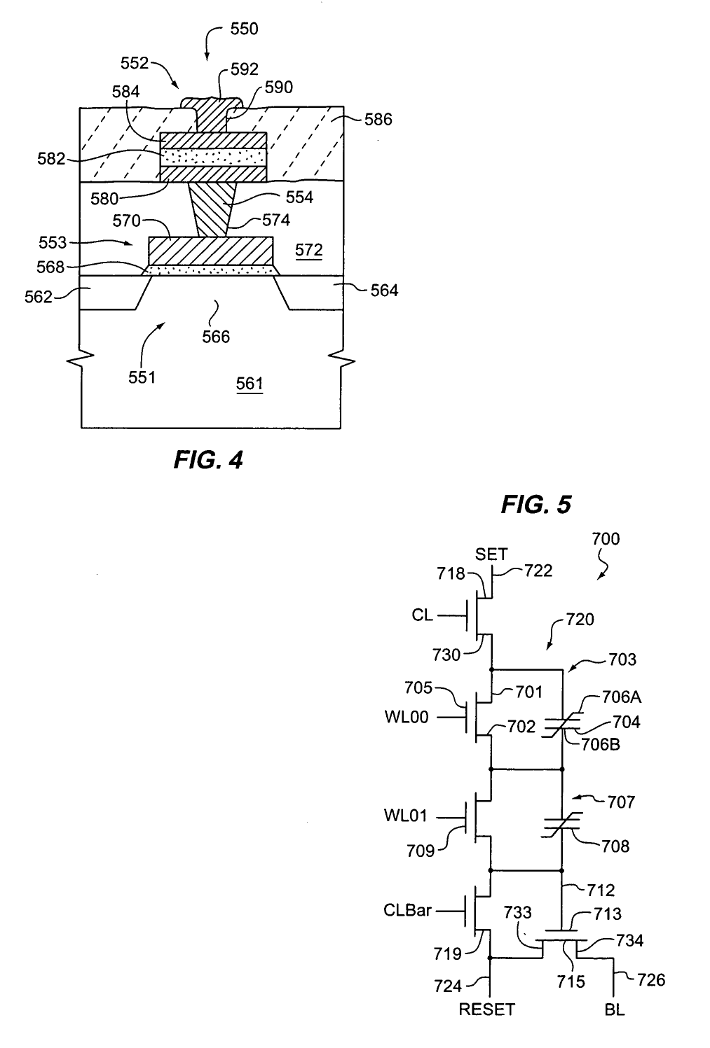

FIG. 4 shows a cross-sectional view of a portion of an MFM-MIS FET memory cell 550 in accordance with a preferred embodiment of the invention. The MFM-MIS FET memory cell 550 comprises a field effect transistor (“FET”) 551, a metal-ferroelectric-metal (“MFM”) capacitor 552, and metal-insulator-semiconductor (“MIS”) capacitor 553 connected in series with MFM capacitor 552 by an interconnect 554. In an MFM-MIS memory, MIS capacitor 553 is part of FET 551. MFM-MIS FET memory cell 550 is formed on semiconductor substrate 561, which includes a highly doped source region 562, a highly doped drain region 564, and a channel region 566. FET 551 comprises source region by 562, drain region by 564, channel region by 566, gate oxide layer 31 and gate electrode 570. MIS capacitor 553 comprises gate electrode 570, gate oxide 568 and semiconductor substrate 561. FET 551 and MIS 553 are covered by a standard interlayer dielectric (“ILD”) 572, comprising a glasseous oxide, preferably a.:boron-doped phosphosilicate glass (“BPSG”). A via 574 from the top of ILD 572 down to the surface of gate electrode 570 is filled with interconnect 554, typically called a conductive plug. A bottom electrode 580 is located on ILD 572, covering interconnect 554. A ferroelectric thin film 582 is located on bottom electrode 580, and top electrode 584 is located on ferroelectric layered superlattice material thin film 582. Bottom electrode 580, ferroelectric thin film 582, and top electrode 584 together form ferroelectric MFM capacitor 552. A second interlayer dielectric, ILD 586, covers ILD 572 and MFM 552. A wiring hole 590 extends through ILD 586 to top electrode 584. Local interconnect 592 fills wiring hole 590.

FIG. 5 shows an alternative embodiment of a ferroelectric FET memory 700. Memory 700 includes a group 720 of memory cells 703 and 707 connected in series, a read transistor 715, a set transistor 718, and a reset transistor 719. Memory cell 703 includes a ferroelectric capacitor 704 and a transistor 705, with one source-drain 701 of the transistor 705 connected to one electrode 706A of capacitor 704 and the other source-drain 702 of the transistor 705 connected to the other electrode 706B of capacitor 704. Memory cell 707 includes ferroelectric capacitor 708 connected similarly to transistor 709. One end 712 of the series group 720 is connected to the gate 713 of transistor 715, and the other end 730 is connected to the set signal line 722 through transistor 718. The node 712 is also connected to the reset signal line. 724 through reset transistor 719. One source-drain 733 of transistor 715 is connected to reset line 724, while the other source-drain 734 is connected to bit line 726.

The memory 700 is essentially an MFM-MIS FET memory, such as shown in FIG. 4, but with two MFM sections 704 and 707 attached to FET 715. The transistors 705 and 709 short out their respective MFM section when the cell is not selected to be written to or read. While two cells 704 and 707 are shown in the embodiment of FIG. 5, the group 720 can include five, ten, or even twenty or more cells. A complete description of the function of memory 700 is provided in U.S. Provisional Patent Application Ser. No. 60/235,241 filed Sep. 25, 2000 which is incorporated herein by reference as though fully disclosed herein. In addition, the structure of the memory can most easily be implemented if the capacitors 704, 706 etc., are stacked in layers one atop the other. This structure is very practical and dense with the electronic quality thin ferroelectric films that are possible with layered superlattice materials.

Again, the layered superlattice material according to the invention lends itself to this memory. Because very thin functional ferroelectric thin films of layered superlattice material can be made, as compared to prior art ferroelectric materials, the ferroelectric FET takes up only about as much space as a conventional FET. Moreover, the lower crystallization temperatures of the materials according to the invention allow the structures to be even more dense because of less diffusion and other degradation of and between IC components.

The above FETs 40, 370, 514, and 550 and capacitors 528 and 552 illustrate only a few of the many charge storage configurations in which the materials of the invention may be used. Charge storage configurations using any combination of the various layers and features shown in any of the above embodiments may also be utilized.

FIGS. 1-5 depict only a few of the many variations of memory cells that can be fabricated using the method of the invention. The material in accordance with the invention may, in fact, be used in any capacity of any memory cell in which a dielectric or ferroelectric material may be used.

In any of the above embodiments, the conductive barrier layer is preferably IrO₂. The gate insulator layer and or the dielectric buffer layer is preferably tantalum pentoxide (Ta₂O₅), but also may be selected from: SiO₂, CeO₂, ZrO₂, Y₂O₃, YMnO₂, SrTa₂O₆ and the layered superlattice materials according to the invention. If the insulator is SiO₂, its thickness is preferably 4 nm to 20 nm; for other materials it is preferably 4 nm to 50 nm.

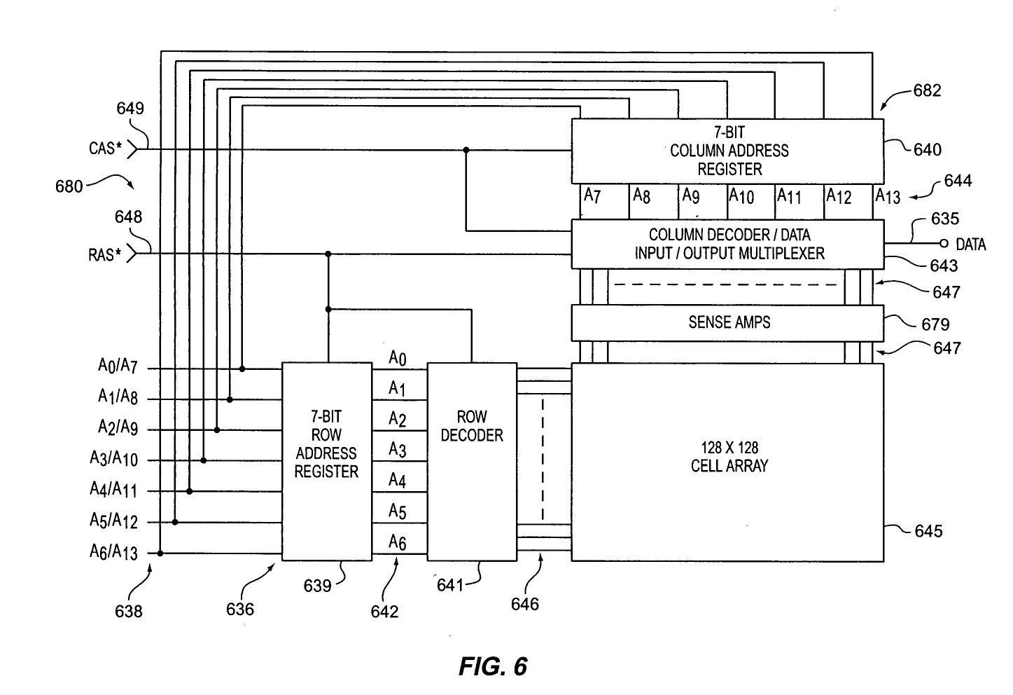

FIG. 6 is a block diagram illustrating an exemplary integrated circuit memory 636 in which the memory cells of FIGS. 1-5 made with the materials of the invention are utilized. For simplicity, the embodiment shown is for a 16K×1 DRAM; however, the material may be utilized in a wide variety of sizes and types of memories, both volatile and non-volatile. In the 16K embodiment shown, there are seven address input lines 638 which connect to a row address register 639 and a column address register 640. The row address register 639 is connected to row decoder 641 via seven lines 642, and the column address register 640 is connected to a column decoder/data input output multiplexer 643 via seven lines 644. Row decoder 641 is connected to a 128×128 memory cell array 645 via 128 lines 646, and column decoder/data input output multiplexer 643 is connected to the sense amplifiers 79 and memory cell array 645 via 128 lines 647. A RAS* signal line 648 is connected to the row address register 639, row decoder 641, and column decoder/data input/output multiplexer 643, while a CAS* signal line 649 is connected to the column address register 640 and column decoder/data input output multiplexer 643. (In the discussion herein, an “*” indicates the inverse of a signal.) An input/output data line 645 is connected to the column decoder/data input output multiplexer 643.

Memory cell array 645 contains 128×128=16,384 memory cells, which is conventionally designated as 16K. These cells may be ferroelectric FET cells, such as shown in FIGS. 1, 2 and 4, FeRAMS or DRAM cells such as shown in FIG. 3, stacked cells such as shown in FIGS. 3-4, groups of cells such as shown in FIG. 5, or any other memory cells useful in integrated circuit memories. Detailed memory architectures of such cells are shown in U.S. patent application Ser. No. 09/385,308 filed Aug. 30, 1999, and U.S. patent application Ser. No. Q9/523,492 filed Mar. 10, 2000, which are hereby incorporated by reference as though fully disclosed herein. They also may be ferroelectric switching capacitor-based cells, dielectric capacitor-based cells, or any other memory cell utilizing the material of the invention.

The operation of the memory in FIG. 6 is as follows. Row address signals A₀ through A₆ and column address signals A₇ through A₁₃ placed on lines 638 are multiplexed via address registers 639, 640 and the RAS* and CAS* signals to row decoder 641 and column decoder/data input/output multiplexer 643, respectively. Row decoder 641 places a high signal on the one of the wordlines 636 that is addressed. Column decoder/data input output multiplexer 643 either places the data signal on line 645 on the one of the bit lines 647 corresponding to the column address, or outputs on the data line 645 the signal on the one of the bit lines 647 corresponding to the column address, depending on whether the function is a write or read function. As is known in the art, the read function is triggered when the RAS* signal precedes the CAS* signal, and the write function is triggered when the CAS* signal comes before the RAS* signal. As is well-known in the art, sense amplifiers 79 are located along lines 647 to amplify the signals on the lines. Other logic required or useful to carry out the functions outlined above as well as other known memory functions is also included in memory 636, but is not shown or discussed as it is not directly applicable to the invention. As outlined above, RAS* and CAS* lines 638 and 639, registers 639, 640, and decoders 641, 642 comprise an information write means 680 for placing the memory cell, such as 40 (FIG. 1), in a first memory state or a second memory state depending upon information input to the memory on data line 645, the first memory cell state corresponding to layer 57 of ferroelectric material being in a first polarization state, and the second memory cell state corresponding to layer 57 being in a second polarization state; these components, plus sense amplifiers 679, comprise an information read means 682 for sensing the state of memory cell, such as 40, and providing an electrical signal corresponding to the state.

It should be understood that memory 436 described above is merely an example of one such memory. Other architectures such as ones in which the data is input on lines connected to rows and output on lines connected to columns, or where there are several different column lines and/or several different row lines associated with each cell, may be used.

It should be understood that the invention contemplates that any and all of the features of the various embodiments of the memory cells disclosed above can be combined with each other. That is, the embodiments shown are exemplary and have been chosen to illustrate the respective features, and are not intended to be limiting to the particular combinations shown.

Another significant advantage of layered superlattice materials for the charge storage elements in a FET is the fact that they generally have dielectric constants in the range of 60 to 200. Prior ferroelectric materials, such as PZT, have dielectric constants well over 300. When a FET is made using a metal oxide on a silicon substrate, a thin film of silicon dioxide forms between the ferroelectric material and the silicon substrate. This thin film forms a parasitic capacitor of relatively low dielectric constant, i.e., about 4, in series with the ferroelectric capacitor. In other cases, such as shown in FIG. 1, a buffer or adhesive dielectric material 52, 53 is intentionally formed between the ferroelectric material and the substrate. This buffer material usually has a dielectric constant higher than 4, but less than 200. As is known in the art, when a voltage is placed across a number of capacitors in series, the voltage drop across each capacitor is inversely proportional to the capacitance, which is generally proportional to the dielectric constant. Thus, when a voltage is placed on gate electrode 58 (FIG. 1) for a FET using prior art materials such as PZT, most of the voltage drop occurs across the parasitic capacitance, or the buffer or adhesive layers. Since the inventive layered superlattice material generally has a dielectric constant about one-third or less of that of prior art ferroelectric materials used in FETs, the voltage drop across the layered superlattice material is more than three times the voltage drop across prior art ferroelectric FETs. Likewise, a layered superlattice material lends itself to being the charge storage element in a DRAM because its dielectric constant is much higher than conventional DRAM storage element materials, such as silicon dioxide, but not so high that it becomes ineffective due to parasitic capacitances in series.

3. Description of The Preferred Formulations

An important aspect of the invention is a class of materials formed by substituting lanthanide series elements for A-site elements and superlattice generator elements in known formulations of layered superlattice materials.

### EXAMPLE 1

### Smeared Bismuth Compounds

A particularly effective substitution is to partially substitute a lanthanide series element for bismuth in a bismuth layered material, which we refer to herein as a smeared bismuth compound. By “partially substituting” means that a larger amount of material is substituted than generally would come under the term “doping”, but not so much as to completely replace the bismuth. Generally if 1% or less of an element is replaced by another element, then the substitution is considered to be doping. In the materials according to the invention, the substitution is 5% or more, and preferably 10% to 80%. Most preferably, from 10% to 30% of the bismuth sites are replaced by a lanthanide series element.

The smeared bismuth compounds are typically what Smolenskii refers to as “Type I” compounds. The materials according to the invention typically have the formula Aₘ₋₁Bi₂MₘO₃ₘ₊₃, where A is an A-site element, M is a B-site element, and m is generally an integer, but also may be fractional. This class of materials according to the invention has the formula Aₘ₋₁(Bi_{1-X}Lan_{X})₂MₘO₃ₘ₊₃, where A, M, and m are as in the Smolenskii Type I formula, and Lan represents a lanthanide, i.e., one or more of lanthanum, cerium, praseodymium, neodymium, promethium, samarium, europium, gadolinium, terbium, dysprosium, holmium, erbium, thulium, ytterbium, and lutetium.

A basic smeared bismuth/lanthanide compound is (Bi_{1-X}Lan_{X})₄Ti₃O₁₂ where 0<x<1. Preferably, 0.1≦x≦0.9, and most preferably 0.1≦x≦0.5. This compound by itself has been found to have excellent electronic properties. Examples of this smeared bismuth/lanthanide compound are (Bi_{1-X}Nd_{X})₄Ti₃O₁₂, (Bi₁₋₁Yb_{X})₄Ti₃O₁₂, (Bi_{1-X}Pr_{X})₄Ti₃O₁₂, (Bi_{1-X}Gd_{X})₄Ti₃O₁₂, and (Bi_{1-X}La_{X})₄Ti₃O₁₂, where x is given above. (Bi_{1-X}La_{X})₄Ti₃O₁₂ is sometimes referred to as BLT in the art. Thin films of all these compounds can be made easily, as described in detail below using commercially available precursors available from Alpha Aesar, 30 Bond Street, Ward Hill, Mass. 01835 USA, Telephone: 1-978-521-6300; Fax: 1-978-521-6350; e-mail: info@alfa.com; and website: www.alfa.com. The isopropoxide precursor is preferable. Typical precursors for (Bi_{1-X}Dy_{X})₄Ti₃O₁₂, (Bi_{1-X}Ce_{X})₄Ti₃O₁₂, (Bi_{1-X}Pm_{X})₄Ti₃O₁₂, (Bi_{1-X}Sm_{X})₄Ti₃O₁₂, (Bi_{1-X}Eu_{X})₄Ti₃O₁₂, (Bi_{1-X}Tb_{X})₄Ti₃O₁₂, (Bi_{1-X}Ho_{X})₄Ti₃O₁₂, (Bi_{1-X}Er_{X})₄Ti₃O₁₂, (Bi_{1-X}Tm_{X})₄Ti₃O₁₂, and (Bi_{1-X}Lu_{X})₄Ti₃O₁₂ are given in Table I below.

Another basic smeared bismuth/lanthanide compound is (Bi_{1-X}Lan_{X})₂O₃, where Lan represents a lanthanide, i.e., one or more of lanthanum, cerium, praseodymium, neodymium, promethium, samarium, europium, gadolinium, terbium, dysprosium, holmium, erbium, thulium, ytterbium, and lutetium, and 0<x<1. Preferably, 0.1≦x≦0.9, and most preferably 0.1≦x≦0.5. These compounds by themselves are generally not layered superlattice materials. However, by combining precursors for these compounds with other metal oxide precursors, as discussed below, layered superlattice materials with excellent electronic properties can be made.

The basic smeared bismuth/lanthanide compounds listed above can be combined with precursors for simple metal oxides to make other smeared bismuth/lanthanide layered superlattice materials. For example, precursors for. strontium oxide, SrO, and tantalum oxide, Ta₂O₅, when mixed with a precursor for the smeared bismuth/lanthanide (Bi_{1-X}Lan_{X})₂O₃, form a precursor for the layered superlattice materials Sr(Bi_{1-X}Lan_{X})₂Ta₂O₉. An example of this material is Sr(Bi_{1-X}Dy_{X})₂Ta₂O₉, where 0<x<1. Preferably, 0.1≦x≦0.9, and most preferably 0.1≦x≦0.5. Other examples of such materials are Pb(Bi_{1-X}Lan_{X})₂Nb₂O₉, Ca(Bi_{1-X}Lan_{X})₂Ta₂O₉, Ba(Bi_{1-X}Lan_{X})₂Ta₂O₉, and A(Bi_{1-X}Lan_{X})₂Ta_{1-y}Nb_{y}O₉ in general where A=Sr, Ca, Ba, or Pb and 1≦y≦0, and x and Lan are given as above. These are all Smolenskii Type I compounds with m=2.

As another example, the basic (Bi_{1-X}Lan_{X})₂O₃ precursor can be mixed with the precursor for Bi₄Ti₃O₁₂ to produce a generalized class of materials with the formula (Bi_{1-X}Lan_{X})₂Bi₄Ti₃O₁₅ where Lan is one of the lanthanides listed above and 0<x1. Preferably, 0.1≦x≦0.9, and most preferably 0.1≦x≦0.5. When x=0.5, this reduces to Bi₅LanTi₃O₁₅, where again Lan can be any of the lanthanides. These are all Smolenskii Type I compounds with m=4.

Precursors for the ABO₃ metal oxides, commonly called perovskites, can be mixed with the basic smeared bismuth lanthanide compounds to create layered superlattice materials with good electronic properties. One subclass of such materials is made by mixing one part of an ABO₃-type metal oxide precursor with one part of a (Bi_{1-X}Lan_{X})₄Ti₃O₁₂ smeared metal oxide. precursor. A basic formulation of such a material is A(Bi_{1-X}Lan_{X})₄Ti₄O₁₅. Specific examples of such compounds are Sr(Bi_{1-X}Lan_{X})₄Ti₄O₁₅, made from a combination of the SrTiO₃ precursor with the (Bi_{1-X}Lan_{X})₄Ti₃O₁₂ precursor; Ca(Bi_{1-X}Lan_{X})₄Ti₄O₁₅, made from a combination of the CaTiO₃ precursor with the (Bi_{1-X}Lan_{X})₄Ti₃O₁₂ precursor; and Pb(Bi_{1-X}Lan_{X})₄Ti₄O₁₅, made from a combination of the PbTiO₃ precursor with the (Bi_{1-X}Lan_{X})₄Ti₃O₁₂ precursor. Likewise, A can be barium. These are all Smolenskii Type I compounds with m=4.

Another subclass of such materials is made by mixing two parts of an ABO₃-type metal oxide precursor with one part of a (Bi_{1-X}Lan_{X})₄Ti₃O₁₂ smeared metal oxide precursor. A basic formulation of such a material is A₂(Bi_{1-X}Lan_{X})₄Ti₅O₁₈. Specific examples of such compounds are Sr₂(Bi_{1-X}Lan_{X})₄Ti₅O₁₅, made from a combination of two parts of the SrTiO₃ precursor with one part of the (Bi_{1-X}Lan_{X})₄Ti₃O₁₂ precursor; Ba₂(Bi_{1-X}Lan_{X})4Ti₅O₁₈, made from a combination of two parts of the BaTiO₃ precursor with one part of the (Bi_{1-X}Lan_{X})₄Ti₃O₁₂ precursor; and Pb₂(Bi_{1-X}Lan_{X})₄Ti₅O₁₅, made from a combination of two parts of the PbTiO₃ precursor with one part of the (Bi_{1-X}Lan_{X})₄Ti₃O₁₂ precursor. Likewise, A can also be calcium. These are all Smolenskii Type I compounds with m=5. For other ABO₃-type compounds, see Ferroelectric Crystals, by Franco Jona and G. Shirane, Dover Publications, Inc., New York, N.Y., Chapter V, pp. 216-261, which is hereby incorporated by reference as though fully disclosed herein.

### EXAMPLE 2

### Lanthanide A-Site Materials

Another class of materials are those with a lanthanide in the A-site of a layered superlattice compound. The materials according to the invention typically have the formula (A_{Z-1}Lan_{[2/3]Z})ₘ₋₁Bi₂MₘO₃ₘ₊₃, where A is an A-site element other than a lanthanide, M is a B-site element, Lan is a lanthanide, i.e., one or more of lanthanum, cerium, praseodymium, neodymium, promethium, samarium, europium, gadolinium, terbium, dysprosium, holmium, erbium, thulium, ytterbium, and lutetium, 0<z 1 and m is generally an integer, but also may be fractional. Preferably, 0.1 z 0.9, and most preferably 0.1≦z≦0.5. Some examples of these compounds are Lan_{2/3}Bi₂Ta₂O₉, Lan2/3Bi₂Nb₂O₉, and Lan_{2/3}Bi₂Ta_{y}Nb_{1-y}O₉ in general, where Lan is a lanthanide mentioned above and 0≦y≦1.

### EXAMPLE 3

### Combination Materials

Materials with the combination of a lanthanide in the A-site and smeared bismuth also have good electronic properties. These materials can be written generally as (A_{1-Z}Lan_{[2/3]Z})ₘ₋₁(Bi_{1-X}Lanₓ)₂MₘO₃ₘ₊₃, where 0<z≦1, 0<x<1, and m is generally an integer, but can be fractional. A subclass of these materials are materials in which the A-sites are shared between bismuth and lanthanides. These materials can be written (Bi_{1-Z}Lan_{Z})_{2/3}(Bi_{1-X}Lanₓ)₂B₂O₉ where 0<z<1, 0<x<1, Lan is a lanthanide, and B is a B-site element.

From the above, it is clear that other formulations of the inventive materials can be written. Others can add dopants, fractional m formulations and other elements. The key aspect of the invention is the use of lanthanides in combination with bismuth in a layered superlattice material. Another aspect of the invention is the use of lanthanides as an A-site element in a layered superlattice material.

4. Description of Preferred Methods of Fabrication

In general, some form of heating or annealing of a deposited metal-containing film in oxygen at elevated temperature is necessary for formation and crystallization of the desired layered superlattice material. An important feature of embodiments of the invention is that the maximum temperature and the total heating times at elevated temperature are minimized compared to the prior art. In the embodiments described in detail in this specification, RTP and annealing treatments are conducted in oxygen-containing gas. The invention also includes, however, embodiments in which annealing in an oxygen-containing gas for part of the total time is followed by annealing in an unreactive gas.

Individual precursor compounds of a precursor solution for fabricating a layered superlattice material thin film may be selected from the group including metal alkoxides, metal polyalkoxides, metal beta-diketonates, metal dipivaloylmethanates, metal cyclopentadienyls, metal alkoxycarboxylates, metal carboxylates, metal ethylhexanoates, octanoates, and neodecanoates. A key aspect of the invention is the use of alkoxides of transition metals as precursors, and especially as final precursors. Alcohols that may be used include isopropanol, n-propoxide, 2-methoxyethanol, 1-butanol, 1-pentanol, and 2-pentanol and 2, 4-pentanols. The metal precursor compound may also comprise a metal 2-ethylhexanoate, which is well suited for use in a liquid-source misted chemical deposition (“LSMCD”) technique. An individual metal organic decomposition (“MOD”) precursor compound is formed, for example, by interacting each metal of a desired compound, for example, dysprosium, neodymium, lanthanum, strontium, bismuth, tantalum or niobium, or an alkoxide of the metal, with a carboxylic acid, or with a carboxylic acid and an alcohol, and dissolving the reaction product in a solvent. The alcohols mentioned above may be used in this process also. Carboxylic acids that may be used include 2-ethylhexanoic acid, octanoic acid, and neodecanoic acid, preferably 2-ethylhexanoic acid. Solvents that may be used include xylenes, n-octane, n-butyl acetate, n-dimethylformamide, 2-methoxyethyl acetate, methyl isobutyl ketone, and methyl isoamyl ketone, as well as many others. The metal, metal alkoxide, acid, and alcohol react to form a mixture of metal-alkoxocarboxylate, metal-carboxylate and/or metal-alkoxide, which mixture is heated and stirred as necessary to form metal-oxygen-metal bonds and boil off any low-boiling point organics that are produced by the reaction. Initial MOD precursors are usually made or bought in batches prior to their use; and the final precursor mixtures are usually prepared immediately before application to the substrate. Final preparation steps typically include mixing, solvent exchange, and dilution. The metalorganic precursor compounds may be stored for periods of several months when dissolved in xylenes or n-octane. Table 1 summarizes precursors for various lanthanides that have been used in making the integrated circuit thin films according to the invention.

TABLE 1

| METAL | CHEMICAL NAME OR NAMES |
|---|---|
| Lanthanum | Lanthanum isopropoxide |
| | Lanthanum ethoxide |
| | Lanthanum 2-ethylhexanotate |
| | Lanthanum 2,4-pentanedionate |
| Neodymium | Neodymium isopropoxide |
| | Neodymium hexofluoro-2,4-pentanedionate |
| | Neodymium 1,1,1-trifluoro-2,4-pentonedionate |
| Praseodymium | Praseodymium isopropoxide |
| | Praseodymium hexofluoro-2,4-pentanedionate |
| Dysprosium | Dysprosium isopropoxide |
| | Dysprosium octanoate |
| Ytterbium | Ytterbiium isopropoxide |
| | Ytterbium hexofluoro-2,4-pentanedionate |
| | Ytterbium DPM |
| Gadolinium | Gadolinium isopropoxide |
| | Gadolinium 2,4-pentanedionate |
| Cerium | Cerium isopropoxide |
| Promethium | Promethium isopropoxide |
| Samarium | Samarium isopropoxide |
| Europium | Europium isopropoxide |
| Terbium | Terbium isopropoxide |
| Holmium | Holmium isopropoxide |
| Erbium | Erbium isopropoxide |
| Thulium | Thulium isopropoxide |
| Lutetium | Lutetium isopropoxide |
| Bismuth | Triphenyl bismuth |
| | Triisopropoxy bismuth |
| | Bismuth dipivaloylmethanate |
| Titanium | Titanium Isopropoxide |
| | Diisopropoxy dipivaloylmethanato titanium |
| | Tetraisopropoxy titanium |
| Strontium | Strontium isopropoxide |
| | Dipivaloylmethanato strontium or Bis |
| | (2,2,6,6,-tetramethyl-3,5-heptanedionato)- |
| | strontium or strontium dipivaloylmethanate |
| | Bis (pentamethyl-cyclopentadienyl)-bis (tetrahydrofran) |
| | strontium |
| | Bis (2,2,6,6,-tetramethyl-3,5-heptanedionato)-bis (1,10- |
| | phenanthroline) strontium |
| Tantalum | Tantalum isopropoxide |
| | Pentamethoxy tantalum |
| | Pentaethoxy tantalum |
| | Pentapropoxy tantalum |
| Niobium | Niobium isopropoxide |
| | Pentachloro niobium |
| | Dipivaloylmethanato trichloro niobium |

Pentaethoxy niobium

In Table 1, DPM is C₁₁H₁₉O₂ usually called 2,2,6,6,-tetramethyl-3,5-heptanedione.

In accordance with the invention, the precursor may be applied to a substrate using a conventional liquid deposition technique, such as metalorganic chemical vapor deposition (MOCVD) described in U.S. Pat. No. 5,648,114 issued Jul. 15, 1997 to Paz de Araujo et al., or International Publication No. 99/02756 published 21 Jan. 1999, a misted deposition method as described in U.S. Pat. No. 5,997,642 issued Dec. 7, 1999 to Solayappan et al., or a spin-coating method as described in U.S. Pat. No. 5,519,234 issued May 21, 1996 to Paz de Araujo et al., or any of the processes described in U.S. Pat. No. 6,056,994 issued May 2, 2000 to Paz de Araujo et al., all of which documents are incorporated herein by reference as though fully disclosed herein. In Example 4 below, a liquid precursor was applied using an MOCVD technique. In Example 5 below, a liquid precursor was applied using a spin-on process. In Example 6 below, a liquid deposition process utilizing misted deposition was used.

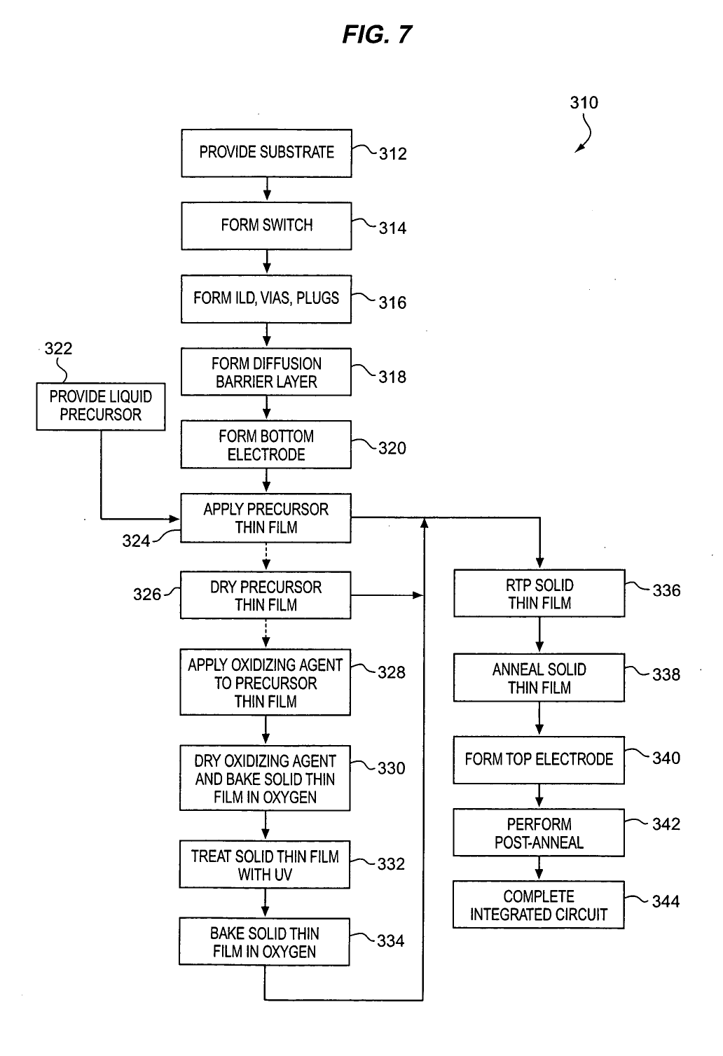

The diagram of FIG. 7 is a flow sheet of the fabrication steps of methods in accordance with the invention to make a ferroelectric memory as depicted in FIG. 3. The preferred method 310 of FIG. 7 uses an MOCVD technique, though the figure includes other embodiments as well. Other methods may also be used. Although method 310 is discussed herein with reference to FIG. 3, it is clear that the method of FIG. 7 and numerous variations of methods in accordance with the invention may be used to fabricate thin films of polycrystalline layered superlattice materials of other compositions according to the invention in various types of ferroelectric structures of the integrated circuit art.

In step 312 of FIG. 7, a semiconductor substrate is provided on which a switch is formed in step 314. The switch is typically a MOSFET. In step 316, an insulating layer is formed by conventional techniques to separate the switching element from the ferroelectric element to be formed. Using conventional processes, the insulating layer is patterned to form vias, which are filled with conductive plugs to electrically connect the switch to the memory capacitor and the rest of the integrated circuit. In step 318, a diffusion barrier layer is deposited on the insulating layer and patterned. Preferably, the diffusion barrier comprises titanium nitride and has a thickness of about 10 nm to 20 nm. Preferably, the diffusion barrier is deposited by a conventional sputtering method, using a titanium nitride target, although a titanium target with a nitrogen-containing sputter gas may also be used. In step 320, a bottom electrode is formed. Preferably, the electrode is made of platinum and is sputter-deposited to form a layer with a thickness of about 200 nm. In step 322, chemical precursors of the layered superlattice material that will form the desired ferroelectric thin film are prepared. Usually, precursor solutions are prepared from commercially available solutions containing the chemical precursor compounds. Such commercial solutions are available from Alfa Aesar noted above, Kojundo Chemical, Tokyo Japan, and others. If necessary, the concentrations of the various precursors supplied in the commercial solutions are adjusted in step 322 to accommodate particular manufacturing or operating conditions. Preferred embodiments of the inventive method utilize a final liquid precursor solution containing relative molar proportions of one or more of the elements lanthanum, cerium, praseodymium, neodymium, promethium, samarium, europium, gadolinium, terbium, dysprosium, holmium, erbium, thulium, ytterbium, and lutetium. The precursor thin film is applied at step 324.

In the preferred embodiment, the application of the precursor is via MOCVD, as described, for example, in U.S. Pat. No. 5,648,114 issued Jul. 15, 1997 to Paz de Araujo et al., or International Publication No. 99/02756 published 21 Jan. 1999. If the MOCVD technique is used, the process proceeds directly to the second column in FIG. 7. After the MOCVD process, an RTP process may optionally be performed. The RTP step takes place at a hold temperature in the range of from 400° C. to 750° C., and preferably between 600° C. and 700° C. for a time between ten seconds and five minutes and preferably from about thirty seconds to two minutes. Several RTP pulses may be used. A furnace anneal step may optionally follow the RTP process, or directly follow the application process 324. If a furnace anneal step is performed, it preferably takes place at a temperature range of 650° C. to 750° C. for from 30 minutes to 90 minutes, and preferably at about 650° C. for about 60 minutes.

It is important in the MOCVD process to use excess bismuth in the precursor. In forming a mist and in the vaporization and deposition processes, bismuth tends to form compounds which vaporize more easily than compounds formed by the other metal in the precursor. The highly volatile bismuth compounds can escape during the misting, vaporization and deposition processes. Thus, to obtain proper stoichiometry in the final thin film, excess bismuth must be added in the precursor.

In an alternative process, process 324 is a process which forms a liquid coating on the substrate, such as misted deposition or spin-on, and then the process proceeds preferably to a drying step 326 and from there directly to either an RTP process 336, an anneal process 338, or both. The drying step preferably takes place at a temperature not exceeding 300° C., on a hot plate in substantially pure O₂ gas, or at least in an oxygen-containing gas, for a time period not exceeding 15 minutes. The RTP process and furnace anneal are preferably at temperatures and for times as described above.

In a second alternative process, a liquid coating of precursor solution is applied to the substrate in step 324 followed by a drying process 326 and an oxidizing process 328. In this case, in drying step 326, the substrate with the coating of liquid precursor is baked and dried at a low temperature, preferably not exceeding 300° C., and preferably being 100° C. or higher. Preferably, the drying step is conducted on a hot plate in substantially pure O₂ gas, or at least in an oxygen-containing gas, for a time period not exceeding 15 minutes. For example, in an actual process used, after use of a spin-coating technique, the liquid precursor thin film was dried using a hot plate at 160° C. for 1 minute, forming a solid precursor thin film. In step 328, a liquid strong oxidizing agent in accordance with the invention is applied to the solid precursor thin film. In the preferred spin-on method, a 5% hydrogen peroxide solution of H₂O₂ in water is applied by spin-coating. In drying and baking step 330, the substrate including the solid precursor thin film and strong oxidation agent is dried and baked at a low temperature not exceeding 300° C., preferably on a hot plate at 160° C. for one minute, forming a solid metal oxide thin film. The step of exposing the precursor thin film to the strong oxidizing agent comprises the combination of steps 328 and 330. In step 332, an optional UV treatment is conducted. The solid metal oxide thin film is preferably treated with ultraviolet radiation (“UV”) for 5 minutes at a wavelength from 150 nm to 350 nm, and preferably about 260 nm wavelength. In heating step 334, the solid metal oxide thin film is baked in oxygen-containing gas at low temperature. If optional UV step 332 was conducted, then heating step 334 preferably includes a hot plate bake at 160° C. for one minute, followed by a hot plate bake at 260° C. for 4 minutes. If optional step 332 was not performed, then, preferably, no 160° C. bake is done in step 334, rather only the 260° C. bake for 4 minutes is performed. Preferably, an RTP step 336 is conducted. The RTP treatment may be conducted in a conventional RTP apparatus. The RTP is conducted at a temperature in a range of from 500° C. to 700° C., for a time period in the range of from 5 seconds to 5 minutes. Preferably, the RTP is conducted at a temperature of 650° C. for 30 seconds with an actual ramping rate in a range of from 10° C. to 100° C. per second, preferably about 50° C. per second. Radiation from a halogen lamp, an infrared lamp, or an ultraviolet lamp provides the source of heat for the RTP step. In the example below, an AG Associates Model 410 Heat Pulser utilizing a halogen source at ambient atmospheric pressure was used. The RTP is performed in an oxygen-containing gas, preferably in substantially pure O₂ gas. Any residual organics are burned out and vaporized during the RTP process. At the same time, the rapid temperature rise of the RTP promotes nucleation; that is, the generation of numerous crystalline grains of layered superlattice material in the solid film resulting from steps 326 through 334. These grains act as nuclei upon which further crystallization can occur. The presence of oxygen in the RTP process enhances formation of these grains.

Anneal step 338 typically involves a furnace anneal of the solid metal oxide thin film at elevated temperature, preferably at 650° C. The furnace anneal in step 338 is performed in an oxygen-containing gas, usually O₂. Preferably, the annealing time of step 338 in oxygen does not exceed 90 minutes. The RTP of step 336 and the oxygen-annealing of step 338 can be conducted in air, in an oxygen-rich gas having an oxygen content greater than that of air, or in an “oxygen-deficient” gas, in which the relative amount of oxygen is less than the relative amount of oxygen in air. Preferably, they are performed in O₂ gas.

Whatever process is used to form the layered superlattice material thin film, a top electrode is formed in step 340. Preferably, the electrode is formed by RF sputtering of a platinum single layer, but it also may be formed by DC sputtering, ion beam sputtering, vacuum deposition, or other appropriate conventional deposition process. If desirable for the electronic device design, before the metal deposition, the ferroelectric layered superlattice material may be patterned using conventional photolithography and etching, and the top electrode is then patterned in a second process after deposition. In the example described below, the top electrode and layered superlattice material are patterned together using conventional photolithography techniques and ion beam milling.

As deposited, the adhesion of the top electrode to the thin film of layered superlattice material is usually weak. The adhesion is improved by post-annealing in step 342. The post-anneal may be performed in an electric furnace at a temperature between 500° C. and 700° C. A post-anneal below 500° C. does not improve the adhesion of the electrode, and the resulting capacitor devices would tend to be extremely leaky, and shorted in the worst cases. Preferably, post-annealing in step 342 is performed at 650° C.

The post-anneal, either a conventional furnace post-anneal for about 30 minutes to 60 minutes, or alternatively an RTP post-anneal for 5 seconds to 5 minutes, or both, releases the internal stress in the top electrode and in the interface between the electrode and the ferroelectric thin film. At the same time, the post-anneal step 342 reconstructs microstructures in the layered superlattice material resulting from the sputtering of the top electrode, and as a result improves the properties of the material. The effect is the same whether the post-anneal is performed before or after the patterning steps mentioned in connection with step 344 below. With regard to most electrical properties, unreactive gas, such as helium, argon, and nitrogen, may be used with approximately the same result as with oxygen, thereby decreasing exposure of the integrated circuit to oxygen at elevated temperature.

The circuit is generally completed in step 344, which can include a number of substeps; for example, deposition of an ILD, patterning and milling, and deposition of wiring layers.

In a further embodiment, a conventional MOCVD apparatus and a MOCVD thin film deposition technique may be modified to fabricate a thin film in accordance with the invention. In one variation, strong oxidizing gas may be added to a CVD reaction chamber during deposition of a precursor thin film. Preferably, about 20 volume-percent of ozone is maintained in the CVD reaction chamber, while the substrate is heated at elevated temperature, preferably at about 650° C. In another variation, instead of using strong oxidizing gas in the reaction chamber, a precursor thin film may be oxidized by using either a liquid or a gaseous strong oxidizing agent after CVD deposition of the precursor thin film, as described above.

In still another embodiment, the thin film is exposed to an oxygen-containing gas under a pressure higher than atmospheric pressure. The exposure to the pressure may occur during deposition, drying, baking or annealing. Preferably, the pressure is between two and ten atmospheres, and most preferably between two and five atmospheres.

### EXAMPLE 4

In this example, (Bi_{1-X}LAN_{X})₄Ti₃O₁₂ capacitors were made from precursor solutions containing bismuth, a lanthanide, and titanium. Various lanthanides, including neodymium, gadolinium, ytterbium, praseodymium, and lanthanum were used, with various concentrations of the lanthanide from 0.1≦x≦0.9. In all examples, the lanthanide and titanium precursors were isopropoxides, the bismuth precursor was triphenyl bismuth, and the solvent was octane. The deposition process was MOCVD at 650° C. followed by RTP at 675° C. and a furnace anneal in oxygen at 650° C. The capacitors formed in this example were similar to that of FIG. 4, but without the FET 551, interconnect 554 and 592, and ILD 586. A series of p-type Si wafer substrates 561 were oxidized to form a layer of silicon dioxide 572. A bottom platinum electrode 580 with a thickness of about 200 nm was sputter-deposited on oxide layer 572. These were annealed 30 minutes in O₂ at 650° C., and dehydrated 30 minutes at 180° C. in low vacuum. The thin film of (Bi_{1-X}LAN_{X})₄Ti₃O₁₂ was formed as described above, platinum was sputter-deposited to make a top electrode layer 584 with a thickness of about 200 nm. The platinum and lanthanide bismuth titanate layers were milled to form the capacitors, and then ashing was performed, followed by a post-anneal for 30 minutes at 650° C. in O₂ gas. The capacitors had a thickness of about 110 nanometers and a surface area just under 8000 μm². Preliminary results indicate that useful capacitors can be made in most instances, though it is necessary to adjust deposition and anneal temperatures to obtain optimal results. The best results were for neodymium, which appears to yield capacitors having polarizabilities as high as 40 μC/cm², which is higher than any prior layered superlattice material.

### EXAMPLE 5

In this example, bismuth lanthanum titanate (BLT) integrated circuit thin film capacitors were fabricated by misted deposition. As indicated above, the general formula for BLT is preferably (Bi_{1-X}La_{X})₄Ti₃O₁₂, though other equivalent formulations are 10 sometimes used in the art. In this example, the precursor was a mixture of lanthanum isopropoxide, triphenyl bismuth, and titanium isopropoxide with the proportions such that a BLT material having the formula (Bi_{3.25}La_{0.75})₄Ti₃O₁₂ would be produced. The capacitors formed in this example were similar to that of FIG. 4, but without the FET 551, interconnect 554 and 592, and ILD 586. A series of p-type Si wafer substrates 561 were oxidized to form a layer of silicon dioxide 572. A bottom platinum electrode 580 with a thickness of about 200 nm was sputter-deposited on oxide layer 572. These were annealed 30 minutes in O₂ at 650° C., and dehydrated 30 minutes at 180° C in low vacuum. The thin film of BLT was formed by spin-on deposition using the precursor as described above, followed by drying on a hot plate at 300° C. for five minutes, rapid thermal annealing (RTA) at 675° C. for thirty seconds, and furnace annealing in oxygen at 650° C. for 60 minutes. Platinum was sputter-deposited to make a top electrode layer 584 with a thickness of about 200 nm. The platinum and bismuth lanthanum tantalate layers were milled to form the capacitors, and then ashing was performed, followed by a post-anneal for 30 minutes at 650° C. in O₂ gas. The capacitors had a thickness of about 110 nm and a surface area of 7850 μm². Polarizability, 2Pr, was 12.65 μC/cm² at three volts and rose to 18.10 μC/cm² at 10 volts. The coercive voltage was 175.4 at 3 volts and rose to 235.12 at ten volts. Leakage current was 10⁻⁶ amperes per cm² or less out to nearly five volts.

The same process was performed except that the furnace anneal was raised to 700° C. Polarizability, 2Pr, was now 17.60 μC/cm² at 3 volts and rose to 22.32 μC/cm² at 10 volts. The coercive voltage was 177.95 at 3 volts and rose to 216.79 at ten volts. Leakage current was 10⁻⁶ amperes per cm² or less out to four volts.

### EXAMPLE 6

In this example, integrated circuit thin film capacitors were fabricated from a dysprosium bismuth tantalate (DBT) liquid precursor solution, the ingredients of which are shown in Table 2.

TABLE 2

| Compound | FW | g | Mmcle | equiv | Vendor | Lot # |
|---|---|---|---|---|---|---|
| Dysprosium | 9,017.1 | 5.5834 | 0.6192 | 0.6667 | Sy- | Sep. 27, |
| octanoate | | | | | metrix | 1993 |
| in xylenes | | | | | | |
| Bi₂Ta₂O₈ | 5,000 | 4.6439 | 0.9288 | 1.000 | Sy- | Jul. 26, |
| solution in | | | | | metrix | 1993 |
| xylenes | | | | | | |
| Bismuth | 753.080 | .0700 | 0.0930 | 0.1001 | Strem | 135617- |
| 2-ethyl- | | | | | | S |
| hexanoate | | | | | | |

The solution contained amounts of chemical precursors corresponding to the stoichiometric formula Dy2/3Bi_{2.2}Ta₂O₉. The precursor solution contained the following initial precursors: dysprosium octanoate in xylenes, a bismuth tantalate solution in xylenes, and bismuth 2-ethylhexanoate. The chemicals were combined in a flask, heated and stirred while allowing the volume to reduce from about 10 ml to about 5 ml. The solution was then diluted to 6.0 ml with xylenes to produce a final precursor of about 0.155 mol/l. The capacitors were formed using one sequence of applying a precursor coating and strong oxidizing agent with corresponding heating steps, and the ferroelectric thin films had a thickness of about 100 nm.

The capacitor formed in this example was similar to that of FIG. 4, but without the FET 551, interconnect 554 and 592, and ILD 586. A series of p-type Si wafer substrates 561 were oxidized to form a layer of silicon dioxide 572. A bottom platinum electrode 580 with a thickness of about 200 nm was sputter-deposited on oxide layer 572. These were annealed 30 minutes in O₂ at 650° C., and dehydrated 30 minutes at 180° C. in low vacuum. A spincoat of the 0.12 molar solution of the DBT-precursor was deposited on the bottom electrode 580 at 1800 rpm for 30 seconds. This was dried by heating on a hot plate in O₂ gas for one minute at 160° C., forming a solid precursor thin film. A liquid strong oxidizing agent was applied to the precursor thin film on the wafer by spin-coating. Approximately 20 ml of 5% H₂O₂ in water was applied to the center of the wafer, spun at 500 rpm for 5 seconds, and then at 1500 rpm for 30 seconds. The spin-coating of strong oxidizing agent was dried and baked on a hot plate in O₂ gas at 160° C. for one minute, and then at 260° C. for 4 minutes. The resulting metal oxide thin film on the wafer was then treated using rapid-thermal-processing (RTP) at 650° C. for 30 seconds in O₂ gas, with a ramping rate of 100° C. per second. The wafer and coating were annealed for 90 minutes at 625° C. in an atmosphere of “wet” O₂ gas. The “wet” oxygen gas was produced by bubbling O₂ gas through water at 95° C. before flowing it into the annealing furnace. These steps formed a ferroelectric thin film 582 having a thickness of about 90 nm and containing dysprosium bismuth tantalate layered superlattice material. Platinum was sputter-deposited to make a top electrode layer 584 with a thickness of about 200 nm. The platinum and dysprosium bismuth tantalate layers were milled to form the capacitors, and then ashing was performed, followed by a post-anneal for 30 minutes at 650° C. in O₂ gas. The capacitors had a surface area of about 8000 μm² The ferroelectric and electronic properties of the dysprosium bismuth tantalate capacitors made according to the invention were studied by measuring hysteresis curves, polarizability, leakage current, and coercive field. The measured remnant polarization, Pr, expressed as the 2Pr-value, was about 16 μC/cm² at 5 volts. The other parameters were within the ranges of prior art layered superlattice materials.

A key feature of the invention is the fact that it is possible to use isopropoxides for the precursors of all the lanthanides. All lanthanides form isopropoxides, as do other elements useful in the compounds mentioned above, such as titanium. This makes it possible to form precursors in which all the metals other than bismuth are isopropoxides. This makes it much simpler to store, mix, and generally handle the precursors in the commercial manufacturing process.

Another feature of the invention is the use of octane as a solvent in the spin-on and misted deposition processes that include a carboxylate. The lanthanide precursors are all soluble in octane, which is a much easier solvent to use than many of the more conventional solvents, since it is not as toxic.

There have been described what are at present considered to be the preferred embodiments of the invention. It will be understood that the invention can be embodied in other specific forms without departing from its spirit or essential characteristics. For example, while the invention has been described in terms of a silicon substrate, other substrates, such as gallium arsenide, germanium, silicon germanium, and other substrates may be used. Many other ferroelectric and dielectric structures can be used. Further, now that the advantages and workability of a ferroelectric or dielectric made with the layered superlattice materials utilizing lanthanides have been demonstrated, many other layered superlattice materials utilizing lanthanides may be devised. The present embodiments are, therefore, to be considered as illustrative and not restrictive. The scope of the invention is indicated by the appended claims.

1-51. (Canceled).

52. A method of fabricating a memory device, said method comprising:
providing a substrate;
forming on said substrate a memory cell,
said process of forming said memory cell on said substrate including utilizing MOCVD to form a layered superlattice material structure in a thin film, said layered superlattice material including an element selected from the group consisting of cerium, praseodymium, neodymium, promethium, samarium, europium, gadolinium, terbium, dysprosium, holmium, erbium, thulium, ytterbium, and lutetium; and
completing said memory on said substrate.

53. A method of fabricating a memory device as in claim 52 wherein said layered superlattice material also includes bismuth.

54. A method of fabricating a memory device as in claim 52 wherein said layered superlattice material also includes titanium.

55. A method of fabricating a memory device as in claim 52 wherein said layered superlattice material further comprises lanthanum.

56. A method of fabricating a memory device as in claim 52 wherein said element comprises neodymium.

57-74. (Canceled).

75. A method of fabricating a ferroelectric layered superlattice material comprising the steps of:
providing a substrate;
providing a liquid precursor including a plurality of metals suitable for forming a layered superlattice material, said metals including an element selected from the group consisting of cerium, praseodymium, neodymium, promethium, samarium, europium, gadolinium, terbium, dysprosium, holmium, erbium, thulium, ytterbium, and lutetium;
applying said precursor liquid to said substrate; and
treating said precursor on said substrate to form a layered superlattice material containing said metal on said first substrate.

76. A method as in claim 75 wherein said precursor liquid comprises a metal compound selected from the group consisting of metal alkoxides and metal carboxylates.

77. and 78. (Canceled).

79. A method as in claim 76 wherein said applying and treating comprises metalorganic chemical vapor deposition (MOCVD).

80. A method as in claim 79 wherein said MOCVD is performed at a temperature of from 500° C. to 850° C.

81. A method as in claim 80 wherein said MOCVD is performed at a temperature of from 500° C. to 700° C.

82-85. (Canceled).

86. A method as in claim 75 wherein said applying comprises a spin-on process.

87. A method as in claim 75 wherein said applying comprises a misted deposition process.

88. A method as in claim 75 wherein said layered superlattice material also includes bismuth.

89. A method as in claim 88 wherein said precursor contains bismuth in excess of the stoichiometric amount required to form said layered superlattice material.

90. A method as in claim 75 wherein said layered superlattice material also includes titanium.

91. A method as in claim 75 wherein said layered superlattice material also comprises lanthanum.

92. A method as in claim 75 wherein said element comprises neodymium.

93-95. (Canceled).

96. A method of fabricating a memory device, said method comprising providing a substrate; forming on said substrate a memory cell, said method characterized by said process of forming said memory cell on said substrate including:
providing a liquid precursor suitable for making a layered superlattice material having the formula Aₘ₋₁(Bi_{1-X}Lan_{X})₂MₘO₃ₘ₊₃, where A is one or more A-site elements, M is one or more B-site elements, O is oxygen, and m is an integer or a fraction, Lan represents one or more of the materials selected from the group consisting of lanthanum, cerium, praseodymium, neodymium, promethium, samarium, europium, gadolinium, terbium, dysprosium, holmium, erbium, thulium, ytterbium, and lutetium, and 0<x<1; and
utilizing said liquid precursor to spontaneously form on said substrate a thin film of a layered superlattice material structure;
said method further comprising completing said memory on said substrate.

97. A method as in claim 96 wherein said utilizing comprises applying said precursor to said substrate in a liquid form.

98. A method as in claim 96 wherein said utilizing comprises applying said precursor to said substrate in a vapor form.

99. A method as in claim 96 wherein said formula comprises (Bi_{1-X}Lan_{X})₄Ti₃O₁₂.

100. A method as in claim 96 wherein said formula comprises A(Bi_{1-X}Lan_{X})₂Ta_{1-y}Nb_{y}O₉ where A=Sr, Ca, Ba, or Pb and 1≦y≦0.

101. A method as in claim 96 wherein said formula comprises (Bi_{1-X}Lan_{X})₂Bi₄Ti₃O₁₅.

102. A method as in claim 96 wherein said formula comprises A(Bi_{1-X}Lan_{X})₄Ti₄O₁₅ where A=Sr, Ca, Ba, or Pb.

103. A method of fabricating a memory device as in claim 96 wherein said layered superlattice material is ferroelectric.

104. A method as in claim 96 wherein said utilizing comprises applying said precursor to said substrate and then treating said substrate to form said layered superlattice material.

105. A method as in claim 104 wherein said applying and treating comprises metalorganic chemical vapor deposition (MOCVD).

106. A method as in claim 104 wherein said treating comprises RTP at a temperature of from 500° C. to 750° C.

107. A method as in claim 104 wherein said applying comprises misted deposition.

108. A method as in claim 104 wherein said applying comprises spin-on deposition.

109. A method as in claim 96 wherein said utilizing comprises MOCVD.

110. A method of fabricating an integrated circuit memory, said method comprising: providing a substrate;
utilizing MOCVD to form a layered superlattice material structure in a thin film, said layered superlattice material having the formula Aₘ₋₁(Bi_{1-X}Lan_{X})₂MₘO₃ₘ₊₃, where A is one or more A-site elements, M is one or more B-site elements, O is oxygen, and m is an integer or a fraction, Lan represents one or more of the materials selected from the group consisting of lanthanum, cerium, praseodymium, neodymium, promethium, samarium, europium, gadolinium, terbium, dysprosium, holmium, erbium, thulium, ytterbium, and lutetium, and 0<x<1; and
completing said integrated circuit memory on said substrate to include said layered superlattice thin film in said integrated circuit.

111. A method of fabricating an integrated circuit memory as in claim 110 wherein said B-site element comprises titanium.

112. A method of fabricating a memory device as in claim 110 wherein said B-site element comprises lanthanum.

113. A method of fabricating a memory device as in claim 110 wherein said Lan comprises lanthanum.

114. A method of fabricating a memory device as in claim 110 wherein said Lan comprises neodymium.

115. A method as in claim 110 wherein said formula comprises (Bi_{1-X}Lan_{X})₄Ti₃O₁₂.

116. A method as in claim 110 wherein said formula comprises A(Bi_{1-X}Lan_{X})₂Ta_{1-y}Nb_{y}O₉ where A=Sr, Ca, Ba, or Pb and 1≦y≦0.

117. A method as in claim 110 wherein said formula comprises (Bi_{1-X}Lan_{X})₂Bi₄Ti₃O₁₅.

118. A method as in claim 96 wherein said formula comprises A(Bi_{1-X}Lan_{X})₄Ti₄O₁₅ where A=Sr, Ca, Ba, or Pb.

119. A method of fabricating a memory device as in claim 110 wherein said layered superlattice material is ferroelectric.
